(19) United States
(12) Patent Application Publication
(10) Pub. No.: US 2026/0143829 A1
(43) Pub. Date: May 21, 2026

(54) PHOTODETECTOR, PHOTOELECTRIC SENSOR, METHODS OF FORMING THE SAME AND DETERMINING CONCENTRATION

(71) Applicant: Nanyang Technological University, Singapore (SG)

(72) Inventors: Munho Kim, Singapore (SG); Yu-Cheng Chen, Singapore (SG); Zhongshu Xiong, Singapore (SG)

(21) Appl. No.: 19/360,014

(22) Filed: Oct. 16, 2025

(30) Foreign Application Priority Data
Nov. 20, 2024 (SG) 10202403627T

(51) Int. Cl. H10F 30/222; G01N 21/33; H10F 71/00; H10F 77/124; H10F 77/14

(52) U.S. Cl. CPC H10F 30/222; G01N 21/33; H10F 71/1274; H10F 71/1276; H10F 77/12485; H10F 77/147

(57) ABSTRACT

A photodetector including a doped gallium nitride (GaN) layer over one or more aluminum gallium nitride (AlGaN) layers. The photodetector may additionally include a first mesa structure on a first portion of the doped gallium nitride (GaN) layer, and a second mesa structure spaced from the first mesa structure and on a second portion of the doped gallium nitride (GaN) layer. The first mesa structure may include a first undoped gallium nitride (GaN) layer on the doped gallium nitride (GaN) layer, and a first aluminum gallium nitride (AlGaN) layer on the first undoped gallium nitride (GaN) layer. The second mesa structure may include a second undoped gallium nitride (GaN) layer on the doped gallium nitride (GaN) layer, and a second aluminum gallium nitride (AlGaN) layer on the second undoped gallium nitride (GaN) layer. The photodetector may also include a first electrode and a second electrode.

### CROSS-REFERENCE TO RELATED APPLICATION

This application claims the benefit of priority of Singapore application No. 10202403627T filed Nov. 20, 2024, the contents of it being hereby incorporated by reference in its entirety for all purposes.

### TECHNICAL FIELD

Various embodiments of this disclosure may relate to a photodetector. Various embodiments may relate to a photoelectric sensor. Various embodiments of this disclosure may relate to a method of forming a photodetector. Various embodiments of this disclosure may relate to a method of forming a photoelectric sensor. Various embodiments of this disclosure may relate to a method of determining a concentration of a substance in a sample.

### BACKGROUND

Nicotinamide adenine dinucleotide (NAD) plays a pivotal role as a coenzyme in redox reactions, alternating between its oxidized form (NAD) and reduced form (NADH). Recent studies have shown that NAD is a critical biomarker for cell redox state. NAD deficiency is reported in neurodegenerative diseases including Alzheimer's and Parkinson's. Conversely, excess levels of NAD are known to be one of the key determinants of cancer. It is reported that cancer cells shift their metabolism towards aerobic glycolysis, as opposed to mitochondrial oxidative phosphorylation. This metabolism shift is marked by an elevated total NAD pool size which can be reflected by the NADH concentration, serving as a potential indicator of cancerous activity.

Various methods have been developed for NADH detection. The conventional enzyme-based electrochemical detection method was reported for NADH in serum, whole blood, and cell suspension samples. Although these methods provide high sensitivity, they have several drawbacks such as limited selectivity, slower response times, enzyme stability issues, and high susceptibility to changes in the sample matrix (e.g., pH, ionic strength). Optical methods utilizing fluorescence probe and autofluorescence were also developed to achieve high sensitivity intracellular NADH detection. These fluorescence-based optical NADH sensors demonstrated high sensitivity while maintaining stability in complex environments. However, these methods are difficult for clinical NADH tests due to the need for bulky and expensive optical instruments, complex signal detection setups, and longer sample preparation periods. Thus, there is a substantial demand to realize a simple, rapid, and sensitive method for NADH quantification.

Optical bioassays based on light absorption are attractive tools owing to its non-invasiveness and simplicity. However, an ultraviolet (UV)-visible spectrometer is required to obtain quantitative results of NADH, which sets a challenge for miniaturization and on-chip sensors. On the other hand, optical absorption could be converted to electrical signals through photodetectors (PDs), which is an alternative for miniaturized on-chip optical bioassays. Given the distinct absorbance disparity between NADH and NAD⁺ at the wavelength of 350 nm, a highly responsive PD at UV wavelength range is essential to achieve on-chip optical assays of NADH. GaN based materials are selected due to their large direct bandgap energy of 3.4 eV. Over the past decades, various types of GaN based PDs have been demonstrated, such as p-i-n, Schottky, avalanche, multiple quantum wells, and metal-semiconductor-metal (MSM). Among various device structures, AlGaN/GaN two-dimensional electron gas interdigitated PDs (2DEG-IPDs) have shown ultralow dark current and ultrahigh UV light responsivity. Therefore, AlGaN/GaN based 2DEG-IPDs are highly suitable for on-chip NADH sensing.

### SUMMARY

Various embodiments may relate to a photodetector. The photodetector may include a semiconductor substrate, and an aluminum nitride (AlN) layer on the semiconductor substrate. The photodetector may also include one or more aluminum gallium nitride (AlGaN) layers over the aluminum nitride (AlN) layer. The photodetector may further include a doped gallium nitride (GaN) layer over the one or more aluminum gallium nitride (AlGaN) layers. The photodetector may additionally include a first mesa structure on a first portion of the doped gallium nitride (GaN) layer, and a second mesa structure spaced from the first mesa structure and on a second portion of the doped gallium nitride (GaN) layer. The first mesa structure may include a first undoped gallium nitride (GaN) layer on the doped gallium nitride (GaN) layer, and a first aluminum gallium nitride (AlGaN) layer on the first undoped gallium nitride (GaN) layer. The second mesa structure may include a second undoped gallium nitride (GaN) layer on the doped gallium nitride (GaN) layer, and a second aluminum gallium nitride (AlGaN) layer on the second undoped gallium nitride (GaN) layer. The photodetector may also include a first electrode over the first mesa structure, and a second electrode over the second mesa structure.

Various embodiments may relate to a photoelectric sensor. The photoelectric sensor may include one or more photodetectors as described herein. The photoelectric sensor may also include an electrically insulating layer over the one or more photodetectors. The photoelectric sensor may further include a holder on the dielectric layer, the holder configured to hold a sample.

Various embodiments may relate to a method of forming a photodetector. The method may include forming an aluminum nitride (AlN) layer on a semiconductor substrate. The method may also include forming one or more aluminum gallium nitride (AlGaN) layers over the aluminum nitride (AlN) layer. The method may further include forming a doped gallium nitride (GaN) layer over the one or more aluminum gallium nitride (AlGaN) layers. The method may additionally include forming a first mesa structure on a first portion of the doped gallium nitride (GaN) layer. The method may also include forming a second mesa structure spaced from the first mesa structure and on a second portion of the doped gallium nitride (GaN) layer. The first mesa structure may include a first undoped gallium nitride (GaN) layer on the doped gallium nitride (GaN) layer, and a first aluminum gallium nitride (AlGaN) layer on the first undoped gallium nitride (GaN) layer. The second mesa structure may include a second undoped gallium nitride (GaN) layer on the doped gallium nitride (GaN) layer, and a second aluminum gallium nitride (AlGaN) layer on the second undoped gallium nitride (GaN) layer. The method may additionally include forming a first electrode over the first mesa structure. The method may also include forming a second electrode over the second mesa structure.

Various embodiments may relate to a method of forming a photoelectric sensor. The method may include forming an electrical insulating layer over one or more photodetectors as described herein. The method may also include forming or providing a holder on the dielectric layer, the holder configured to hold a sample.

Various embodiments may relate to a method of determining a concentration of a substance in a sample. The method may include providing the sample into a photoelectric sensor as described herein. The method may also include illuminating the sample with an ultraviolet (UV) light. The method may additionally include determining a photocurrent from the one or more photodetectors in response to the ultraviolet light passing through the sample. The method may further include determining a concentration of the substance based on the photocurrent.

### BRIEF DESCRIPTION OF THE DRAWINGS

In the drawings, like reference characters generally refer to the same parts throughout the different views. The drawings are not necessarily drawn to scale, emphases instead are generally being placed upon illustrating the principles of various embodiments. In the following description, various embodiments of the invention are described with reference to the following drawings.

FIG. 1 shows a general illustration of a photodetector according to various embodiments.

FIG. 2 shows a general illustration of a photoelectric sensor according to various embodiments.

FIG. 3 shows a general illustration of a method of forming a photodetector according to various embodiments.

FIG. 4 shows a general illustration of a method of forming a photoelectric sensor according to various embodiments.

FIG. 5 shows a general illustration of a method of determining a concentration of a substance in a sample according to various embodiments.

FIG. 6A shows a three-dimensional schematic of a photoelectric sensor according to various embodiments.

FIG. 6B shows a cross-sectional view of a portion of the photoelectric sensor shown in FIG. 6A including one photodetector (biosensor device unit) according to various embodiments.

FIG. 6C shows a microscopy image of (left) the biosensor array (scale bar=500 μm) according to various embodiments; and (right) a photodetector (scale bar=50 μm) according to various embodiments.

FIG. 6D shows a cross-sectional schematic of the photodetector according to various embodiments.

FIG. 6E shows an illustration of a method of forming the photoelectric sensor/photodetector according to various embodiments.

FIG. 7A shows a plot of absorbance (in arbitrary units or a.u.) as a function of wavelength (in nanometers or nm) illustrating the concentration-dependent absorption spectra of reduced from of nicotinamide adenine dinucleotide (NADH) in phosphate-buffered saline (PBS) solution according to various embodiments.

FIG. 7B shows a plot of absorbance (in arbitrary units or a.u.) as a function of wavelength (in nanometers or nm) illustrating the time-resolved absorption spectra of NADH oxidation in the presence of pyruvate in phosphate-buffered saline (PBS) solution according to various embodiments.

FIG. 7C shows a plot of intensity (in arbitrary units or a.u.) as a function of wavelength (in nanometers or nm) illustrating the absorption and fluorescence (emission) spectra of NADH in phosphate-buffered saline (PBS) solution according to various embodiments.

FIG. 8A shows a plot of current (in Amperes or A) as a function of drain-source voltage V_{ds} (in Volts or V) illustrating the dark current I_{dark} and photocurrent Iₚₕ at a wavelength of 355 nm of the photoelectric sensor according to various embodiments.

FIG. 8B shows a plot of photocurrent Iₚₕ (in Amperes or A) of the device unit 1 of the biosensor array as a function of optical power intensity Pₒₚₜ (in milli-Watts per square centimeter or mW/cm²) at 355 nm according to various embodiments.

FIG. 8C shows a plot of responsivity (in Amperes per Watt or A/W) of the device unit 1 of the biosensor array as a function of optical power intensity Pₒₚₜ (in milli-Watts per square centimeter or mW/cm²) at 355 nm according to various embodiments.

FIG. 8D shows an energy band diagram of aluminum gallium nitride/gallium nitride (AlGaN/GaN) heterostructures according to various embodiments.

FIG. 8E shows a plot of responsivity (in Amperes per Watt or A/W) as a function of the device unit number (Unit No.) of the 2×2 biosensors array according to various embodiments (Pₒₚₜ=0.3 mW/cm², λ=355 nm, V_{ds}=5 V).

FIG. 8F shows a plot of absorbance (in arbitrary units or a.u.)/photoresponsivity (in Amperes per Watt or A/W) as a function of wavelength (in nanometers or nm) illustrating the absorption spectrum of NADH/NAD⁺ and the spectral responsivity of the photoelectric sensor according to various embodiments.

FIG. 9A shows plots of photocurrent Iₚₕ (in Amperes or A) of the device units 1 to 4 of the biosensor array as a function of optical power intensity Pₒₚₜ (in milli-Watts per square centimeter or mW/cm²) according to various embodiments.

FIG. 9B shows plots of photocurrent Iₚₕ (in Amperes or A) of the device units 1 to 4 of the biosensor array as a function of wavelength (in nanometers or nm) according to various embodiments.

FIG. 10A shows a schematic illustrating the detection principle of the photoelectric sensor according to various embodiments.

FIG. 10B shows a plot of absorbance (in arbitrary units or a.u.) as a function of NADH concentration (in micrograms per milliliter or μg/mL) illustrating the absorbance of phosphate-buffered saline (PBS) solution with different NADH concentrations according to various embodiments.

FIG. 10C shows a plot of photocurrent Iₚₕ (in Amperes or A) as a function of drain-source voltage V_{ds} (in Volts or V) illustrating the current-voltage relationship of the device unit 1 according to various embodiments with different NADH concentrations.

FIG. 10D shows a plot of photocurrent Iₚₕ (in Amperes or A) as a function of NADH concentration (in microgram per milliliter or μg/mL) illustrating the linear relationship between Iₚₕ and NADH concentration of device unit 1 according to various embodiments at a drain-source voltage of +5 V.

FIG. 10E shows plots of photocurrent Iₚₕ (in Amperes or A) of the device units 1 to 4 of the biosensor array as a function of NADH concentration (in microgram per milliliter or μg/mL) illustrating linear relationship between Iₚₕ and NADH concentration of all four device units according to various embodiments at a drain-source voltage of +5 V.

FIG. 10F shows a plot of limit of detection LOD (in microgram per milliliter or μg/mL) as a function of device unit number (Unit No.) illustrating LOD of all four device units of the biosensor array according to various embodiments.

FIG. 11A shows a plot of photocurrent Iₚₕ (in Amperes or A) as a function of NADH concentration (in microgram per milliliter or μg/mL) illustrating NADH concentration-dependent Iₚₕ for varying chamber height of the photoelectric sensor according to various embodiments from 100 μm to 500 μm.

FIG. 11B shows a plot of limit of detection LOD (in microgram per milliliter or μg/mL) as a function of chamber height (in micrometer or μm) illustrating the effect of chamber height on LOD of the various device units according to various embodiments.

FIG. 12A shows a schematic of NADH sensing with three-dimensional (3D) multicellular models according to various embodiments.

FIG. 12B shows an illustration of on-chip NADH sensing mechanism according to various embodiments.

FIG. 12C shows a plot of normalized photocurrent Iₚₕ as a function of time (in minutes or min) illustrating normalized photocurrent dynamics after adding 500 μM exogenous pyruvate into each type of three-dimensional (3D) multicellular models in device unit 1 according to various embodiments.

FIG. 12D shows a plot of change in photocurrent/initial photocurrent (ΔIₚₕ/Iₚₕ₀) as a function of device unit illustrating ΔIₚₕ/Iₚₕ₀ results of each device unit with 4 types of three-dimensional (3D) multicellular models according to various embodiments.

FIG. 12E shows microscopy images of four three-dimensional (3D) multicellular models with spatial photocurrent/initial photocurrent (ΔIₚₕ/Iₚₕ₀) results from four device units according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g., within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” it is meant including, and limited to, whatever follows the phrase “consisting of”. Thus, the phrase “consisting of” indicates that the listed elements are required or mandatory, and that no other elements may be present.

Embodiments described in the context of one of the photodetectors/photoelectric sensors are analogously valid for the other photodetectors/photoelectric sensors. Similarly, embodiments described in the context of a method are analogously valid for a photodetector/photoelectric sensor, and vice versa.

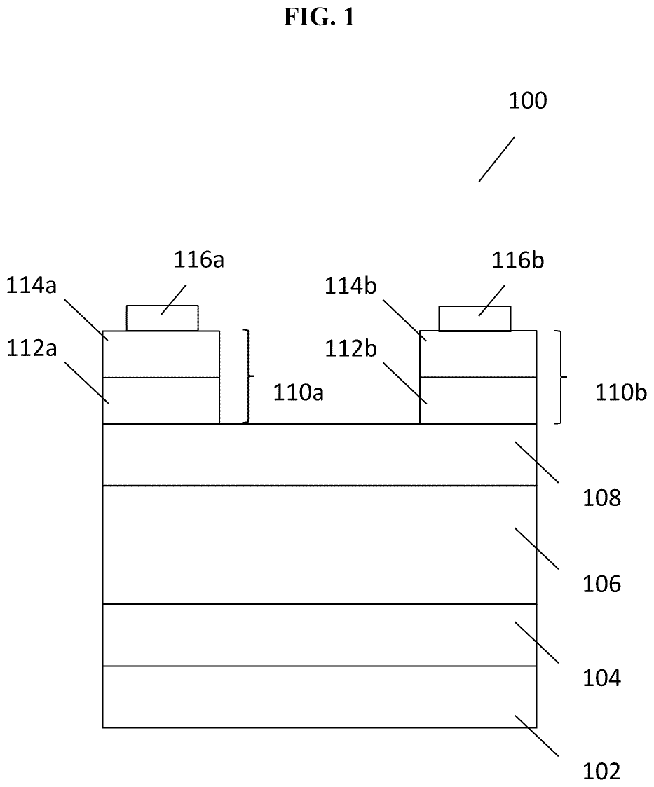

FIG. 1 shows a general illustration of a photodetector according to various embodiments. The photodetector may include a semiconductor substrate 102, and an aluminum nitride (AlN) layer 104 on the semiconductor substrate 102. The photodetector may also include one or more aluminum gallium nitride (AlGaN) layers 106 over the aluminum nitride (AlN) layer 104. The photodetector may further include a doped gallium nitride (GaN) layer 108 over the one or more aluminum gallium nitride (AlGaN) layers 106. The photodetector may additionally include a first mesa structure 110a on a first portion of the doped gallium nitride (GaN) layer 108, and a second mesa structure 110b spaced from the first mesa structure 110a and on a second portion of the doped gallium nitride (GaN) layer 108. The first mesa structure 110a may include a first undoped gallium nitride (GaN) layer 112a on the doped gallium nitride (GaN) layer 108, and a first aluminum gallium nitride (AlGaN) layer 114a on the first undoped gallium nitride (GaN) layer 112a. The second mesa structure 110b may include a second undoped gallium nitride (GaN) layer 112b on the doped gallium nitride (GaN) layer 108, and a second aluminum gallium nitride (AlGaN) layer 114b on the second undoped gallium nitride (GaN) layer 112b. The photodetector may also include a first electrode 116a over the first mesa structure 110a, and a second electrode 116b over the second mesa structure 110b.

In other words, various embodiments may relate to a photodetector with mesa structures 110a, 110b. The mesa structures 110a, 110b may be over the substrate 102, the aluminum nitride (AlN) layer 104, the one or more aluminum gallium nitride (AlGaN) layers 106 and the doped gallium nitride (GaN) layer 108.

For avoidance of doubt, FIG. 1 is intended to illustrate some features of a photodetector according to various embodiments, and is not intended to limit, for instance, the shape, dimensions, orientation etc. of the various features.

In various embodiments, the first mesa structure 110a and the second mesa structure 110b may form an interdigitated arrangement. Each of the first mesa structure 110a and the second mesa structure 110b may have a plurality of teeth. The teeth of the first mesa structure 110a and the teeth of the second mesa structure 110b may formed the interdigitated arrangement, and there may be a spacing or gap between the teeth of the first mesa structure 110a and the teeth of the second mesa structure 110b.

In various embodiments, the doped gallium nitride (GaN) layer 108 may include any suitable dopants, e.g., carbon or iron. In other words, the layer 108 may be doped with any suitable dopants, e.g., carbon or iron.

In various embodiments, the semiconductor substrate 102 may be a silicon substrate, a silicon carbide substrate or a sapphire substrate. For instance, the semiconductor substrate 102 may be the silicon substrate, e.g., a silicon (111) substrate.

In various embodiments, the one or more aluminum gallium nitride (AlGaN) layers 106 may, for instance, include a first aluminum gallium nitride (AlGaN) layer on the aluminum nitride (AlN) layer 104, and a second aluminum gallium nitride (AlGaN) layer on the first aluminum gallium nitride (AlGaN) layer. The second aluminum gallium nitride (AlGaN) layer may have a higher percentage concentration of gallium compared to the first second aluminum gallium nitride (AlGaN) layer. For instance, the second aluminum gallium nitride (AlGaN) layer may be Al_{0.45}Ga_{0.55}N and the first aluminum gallium nitride (AlGaN) layer may be Al_{0.75}Ga_{0.30}N. Generally speaking, a layer of the one or more aluminum gallium nitride (AlGaN) layers 106 further from the aluminum nitride (AlN) layer 104 may have a higher percentage concentration compared to a layer of the one or more aluminum gallium nitride (AlGaN) layers 106 nearer the aluminum nitride (AlN) layer 104.

In various embodiments, the photodetector may be a two-dimensional electron gas interdigitated photodetector (2DEG-IPD). The two-dimensional electron gas (2DEG) may be formed in the first undoped gallium nitride (GaN) layer 112a at the interface with the first aluminum gallium nitride (AlGaN) layer 114a, and in the second undoped gallium nitride (GaN) layer 112b at the interface with the second aluminum gallium nitride (AlGaN) layer 114b.

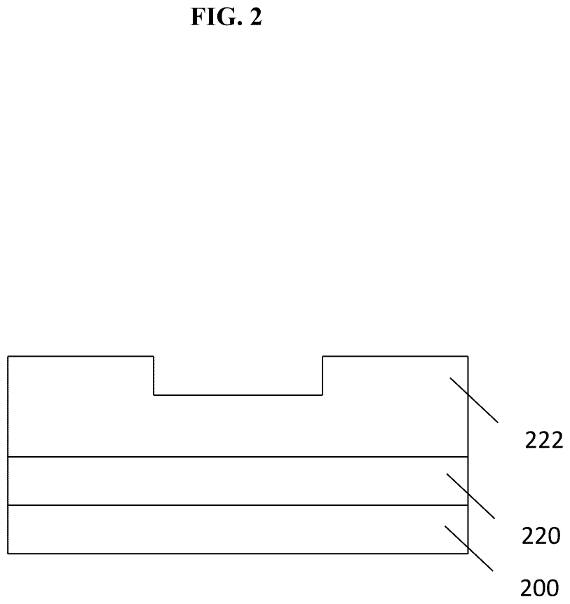

FIG. 2 shows a general illustration of a photoelectric sensor according to various embodiments. The photoelectric sensor may include one or more photodetectors 200 as described herein. The photoelectric sensor may also include an electrically insulating layer 220 over the one or more photodetectors 200. The photoelectric sensor may further include a holder 222 on the dielectric layer 220, the holder 222 configured to hold a sample.

In other words, various embodiments may relate to a photoelectric sensor including one or more photodetectors 200, a holder 222, and an electrically insulating layer 220 between the one or more photodetectors 200 and the holder 222.

For avoidance of doubt, FIG. 2 is intended to illustrate some features of a photoelectric sensor according to various embodiments, and is not intended to limit, for instance, the shape, dimensions, orientation etc. of the various features.

In various embodiments, the electrically insulating layer 220 may include silicon oxide, aluminum oxide, silicon nitride, hafnium oxide, or any combination thereof.

In various embodiments, the holder 222 may include polydimethylsiloxane (PDMS), poly(methyl methacrylate) (PMMA), cyclic olefin copolymer (COC), cyclic olefin polymers (COP), quartz, or any combination thereof. The holder 222 may alternatively be referred to as a chamber.

In various embodiments, the electrically insulating layer 220 may be on portions of the photodetectors. In various embodiments, the first electrode and the second electrode of each of the one or more photodetectors 200 may be exposed through the electrically insulating layer 220.

In various embodiments, the photoelectric sensor may be configured to be used in absorbance-based chemical or biochemical sensing.

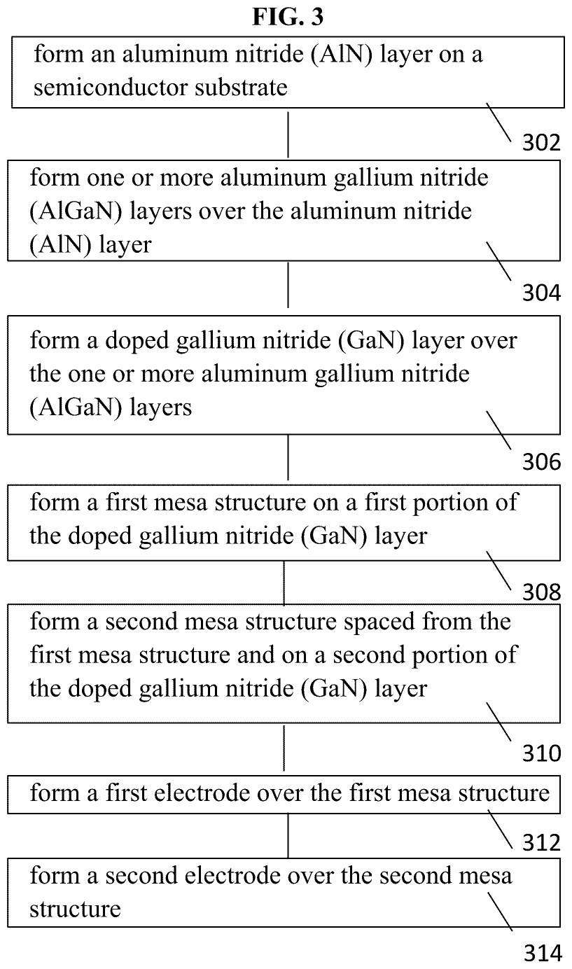

FIG. 3 shows a general illustration of a method of forming a photodetector according to various embodiments. The method may include, in 302, forming an aluminum nitride (AlN) layer on a semiconductor substrate. The method may also include, in 304, forming one or more aluminum gallium nitride (AlGaN) layers over the aluminum nitride (AlN) layer. The method may further include, in 306, forming a doped gallium nitride (GaN) layer over the one or more aluminum gallium nitride (AlGaN) layers. The method may additionally include, in 308, forming a first mesa structure on a first portion of the doped gallium nitride (GaN) layer. The method may also include, in 310, forming a second mesa structure spaced from the first mesa structure and on a second portion of the doped gallium nitride (GaN) layer. The first mesa structure may include a first undoped gallium nitride (GaN) layer on the doped gallium nitride (GaN) layer, and a first aluminum gallium nitride (AlGaN) layer on the first undoped gallium nitride (GaN) layer. The second mesa structure may include a second undoped gallium nitride (GaN) layer on the doped gallium nitride (GaN) layer, and a second aluminum gallium nitride (AlGaN) layer on the second undoped gallium nitride (GaN) layer. The method may additionally include, in 312, forming a first electrode over the first mesa structure. The method may also include, in 314, forming a second electrode over the second mesa structure.

In other words, various embodiments may relate to forming a photodetector with mesa structures. The mesa structures may be over the substrate, the aluminum nitride (AlN) layer, the one or more aluminum gallium nitride (AlGaN) layers and the doped gallium nitride (GaN) layer. Each of the mesa structures may include an undoped gallium nitride (GaN) layer, and an aluminum gallium nitride (AlGaN) layer (also referred to as mesa AlGaN layer) on the undoped GaN layer.

For avoidance of doubt, FIG. 3 is intended to illustrate steps of forming a photodetector according to various embodiments, and is not intended to limit the sequence of the various steps. For instance, step 308 may occur before, after, or at the same time as step 310.

In various embodiments, forming the first mesa structure and the second mesa structure may include depositing undoped gallium nitride (GaN) on the doped gallium nitride (GaN) layer. Forming the first mesa structure and the second mesa structure first mesa structure and the second mesa structure may also include depositing aluminum gallium nitride (AlGaN) on the deposited undoped gallium nitride (GaN), depositing photoresist on the deposited aluminum gallium nitride (AlGaN), patterning the deposited photoresist, and etching the deposited undoped gallium nitride (GaN) and the deposited aluminum gallium nitride (AlGaN) using the patterned photoresist to form the first mesa structure including the first undoped gallium nitride (GaN) layer and the first aluminum gallium nitride (AlGaN) layer, and the second mesa structure including the second undoped gallium nitride (GaN) layer and the second aluminum gallium nitride (AlGaN) layer.

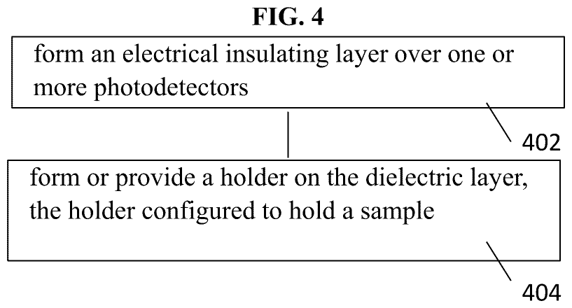

FIG. 4 shows a general illustration of a method of forming a photoelectric sensor according to various embodiments. The method may include, in 402, forming an electrical insulating layer over one or more photodetectors as described herein. The method may also include, in 404, forming or providing a holder on the dielectric layer, the holder configured to hold a sample.

In other words, various embodiments may relate to forming a photoelectric sensor including one or more photodetectors, a holder, and an electrically insulating layer between the one or more photodetectors and the holder.

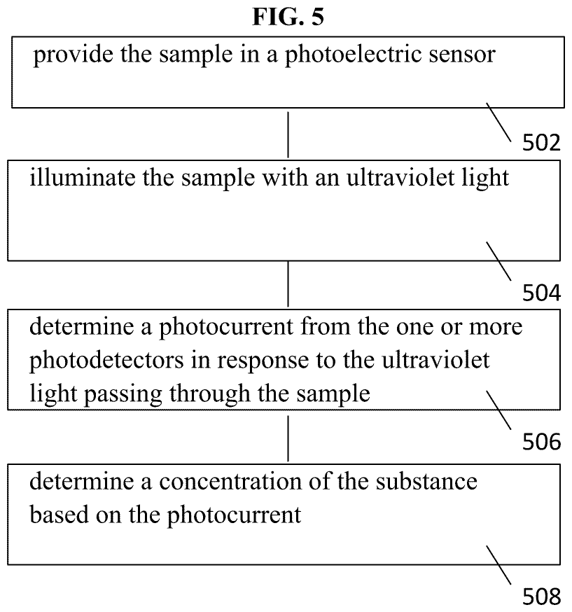

FIG. 5 shows a general illustration of a method of determining a concentration of a substance in a sample according to various embodiments. The method may include, in 502, providing the sample into a photoelectric sensor as described herein. The method may also include, in 504, illuminating the sample with an ultraviolet (UV) light. The method may additionally include, in 506, determining a photocurrent from the one or more photodetectors in response to the ultraviolet light passing through the sample. The method may further include, in 508, determining a concentration of the substance based on the photocurrent.

In other words, various embodiments may relate to determining a concentration of a substance using the photoelectric sensor as described herein.

In various embodiments, determining the concentration of the substance based on the photocurrent may include determining, based on the photocurrent, a change in intensity of the ultraviolet light after passing through the sample. The concentration of the substance may be determined based on the change in intensity of the ultraviolet light. The ultraviolet light may have any wavelength selected from a range from 350 nm to 375 nm, e.g., from 350 nm to 355 nm.

In various embodiments, the substance may be a reduced from of nicotinamide adenine dinucleotide (NADH). As the readout (i.e., measured photocurrent) is based on absorbance change of NADH oxidation, the concentration of any other analyte coupled to NADH formation or consumption may also be determined. For instance, the substance may be glucose, lactate or nitrate. Glucose may be determined via glucose dehydrogenase (linked to NADH formation at 355 nm). Lactate may be determined via lactate dehydrogenase (linked to NADH formation at 355 nm). Nitrate may be determined via nitrate reductase (linked to NADH consumption at 355 nm).

Various embodiments may allow the effective detection of various cellular NADH concentrations by using a miniaturized, rapid on-chip photoelectric sensor scheme based on an AlGaN/GaN two-dimensional electron gas interdigitated photodetector (2DEG-IPD) array. The photoelectric sensor according to various embodiments may include the PD array (including one or more photodetectors (alternatively referred to as biosensor device units or simply device units)) and a PDMS chamber for the detection and analyte containment, respectively. Various embodiments may allow rapid NADH testing with high sensitivity and low power consumption. Despite its straightforward and optical component-free design, the photoelectric sensor according to various embodiments can quantify NADH in a sample of 8 L with an average limit of detection (LOD) as small as 0.7 μg/mL. To prove the sensing ability of the photoelectric sensor according to various embodiments in a real cellular environment, the sensor may be applied in three-dimensional (3D) multicellular models, as they may better mimic the complexity of real tissues compared to 2D cultures, and may provide more accurate cell-cell and cell-matrix interactions critical for studying differentiation, proliferation, and tissue organization. A further study demonstrates that the photoelectric sensor may be capable of distinguishing between normal and cancer cell samples. Therefore, the miniaturized, highly sensitive, and on-chip rapid sensor platform can effectively serve as a diagnostic tool with high-throughput testing capability for point-of-care disease screening and monitoring.

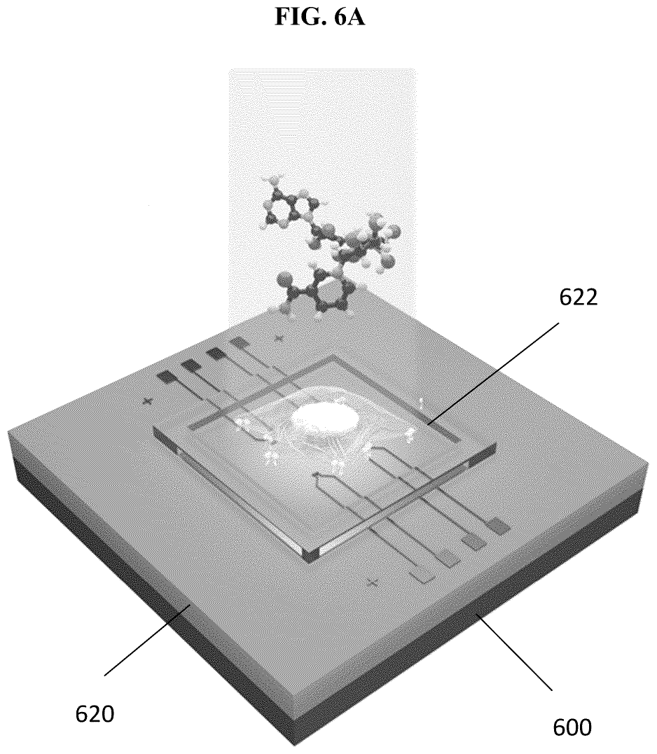

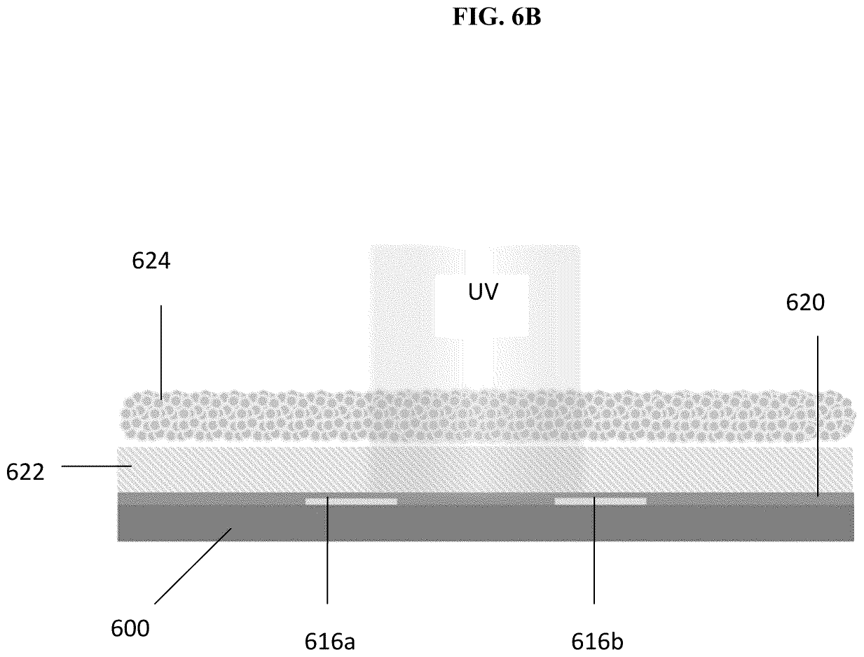

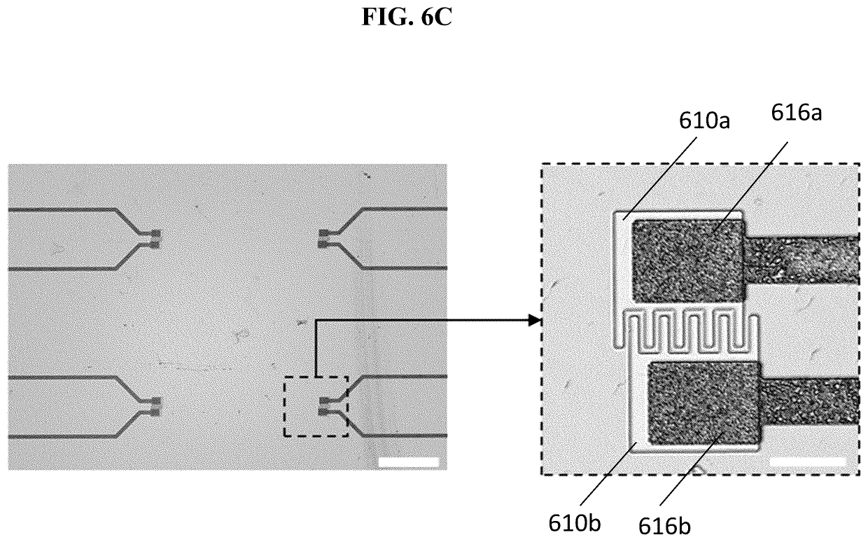

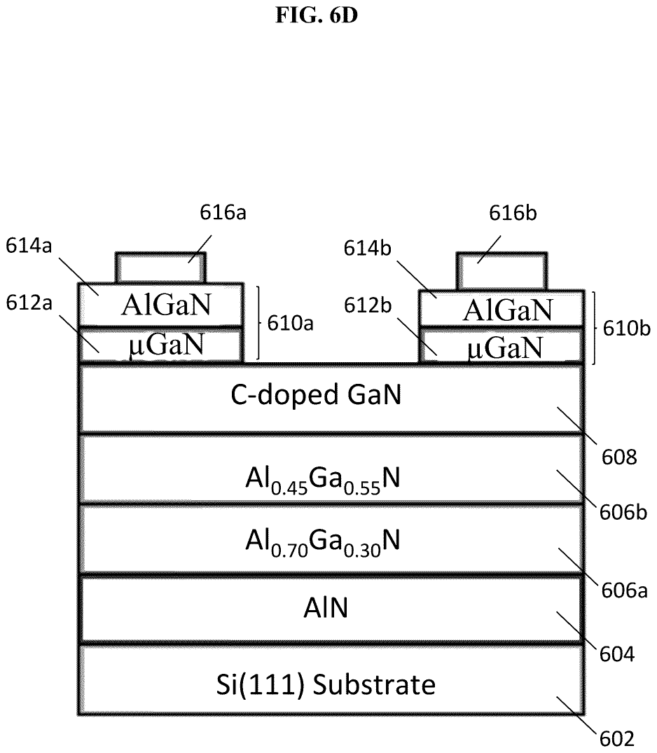

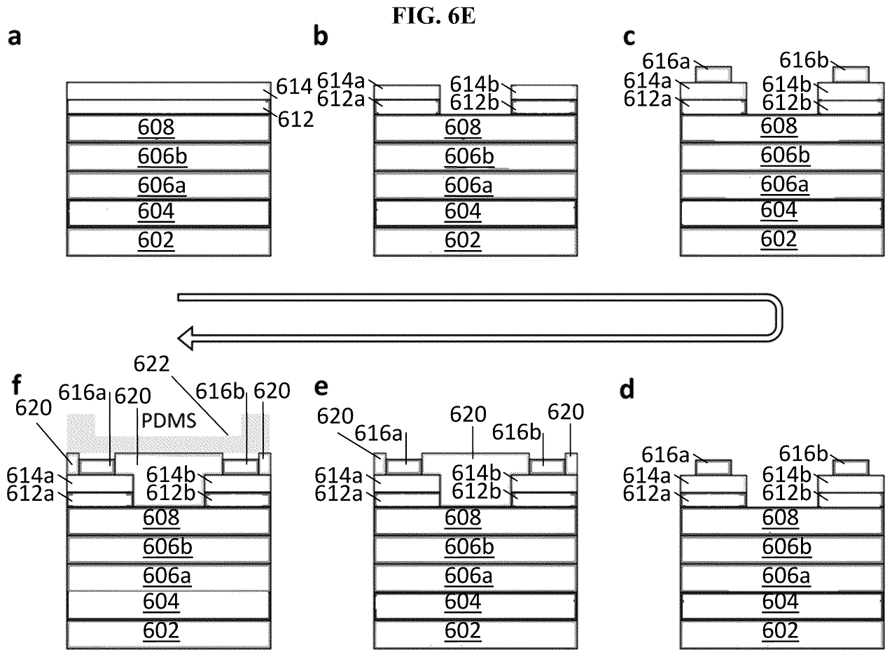

FIG. 6A shows a three-dimensional schematic of a photoelectric sensor according to various embodiments. The photoelectric sensor may alternatively be referred to as a biosensor chip. The photoelectric sensor may include a 2×2 2DEG-IPD biosensor array 600 (i.e., including 4 photodetectors (alternatively referred to as biosensor device units)). FIG. 6B shows a cross-sectional view of a portion of the photoelectric sensor shown in FIG. 6A including one photodetector (biosensor device unit) according to various embodiments. The photoelectric sensor may include an electrically insulating layer 620 (including e.g., silicon oxide (SiO₂) over portions of the 2DEG-IPD biosensors array 600. The photoelectric sensor may also include a holder or chamber 622 (including e.g., polydimethylsiloxane (PDMS)) on the electrically insulating layer 620. The holder 622 may hold 3D multicellular models 624. Each of the photodetectors (biosensor units) may include two electrodes 616a, 616b covered by the electrically insulating layer 620.

FIG. 6C shows a microscopy image of (left) the biosensor array (scale bar=500 μm) according to various embodiments; and (right) a photodetector (scale bar=50 μm) according to various embodiments. FIG. 6D shows a cross-sectional schematic of the photodetector according to various embodiments. FIG. 6E shows an illustration of a method of forming the photoelectric sensor/photodetector according to various embodiments.

FIG. 6E(a) shows the as-grown epi structure. To form the photoelectric sensor/photodetector, the AlGaN/GaN layers 604, 606a, 606b, 608, 612, 614 over silicon Si (111) substrate/wafer 602 may be first diced into 1×1 cm² samples and then cleaned by sonicating in acetone, iso-propanol, and de-ionized water for 5 minutes, respectively. Each device may include e.g., mesa structures 610a, 610b including five pairs of interdigitated teeth (see FIG. 6C), which may be formed by patterning using photolithography and inductive coupled plasma reactive ion etching (ICP-RIE) with an etching depth of above 200 nm to reach the highly resistive carbon-doped GaN layer 608 (FIG. 6E(b)). With reference to FIG. 6D, the photodetector may include an aluminum nitride (AlN) layer 604 on the silicon Si (111) substrate/wafer 602, a first aluminum gallium nitride (Al_{0.70}Ga_{0.30}N) layer 606a on the aluminum nitride (AlN) layer 604, a second aluminum gallium nitride (Al_{0.45}Ga_{0.55}N) layer 606b on the first aluminum gallium nitride (Al_{0.70}Ga_{0.30}N) layer 606a, a carbon (C)-doped gallium nitride (GaN) layer 608 on the second aluminum gallium nitride (Al_{0.45}Ga_{0.55}N) layer 606b. Each mesa structure 610a, 610b may include an undoped gallium nitride (GaN) layer 612a, 612b on the carbon (C)-doped gallium nitride (GaN) layer 608, and an aluminum gallium nitride (AlGaN) layer (i.e., mesa AlGaN layer) 614a, 614b on the respective undoped gallium nitride (GaN) layer 612a, 612b.

Metal stacks 616a, 616b of titanium (Ti)/aluminum (Al)/titanium (Ti)/gold (Au) (thickness=20/150/40/60 nm) may be deposited by electron-beam evaporation (FIG. 6E(c)). Ohmic contact may be formed through rapid thermal annealing at 800° C. under nitrogen (N₂) ambient (FIG. 6E(d)), followed by silicon dioxide (SiO₂) passivation (i.e., forming electrically insulating layer 620) by plasma enhanced chemical vapor deposition (PECVD, FIG. 6E(e)) to avoid unwanted current conduction through the upper chamber 622 loaded with liquid-phase sample 624. The PDMS chamber 622 may be aligned and adhered or bonded over the top of the as-fabricated 2DEG-IPD array 600 (FIG. 6E(f)). The PDMS chamber 622 may be designed in a square shape (4 mm×4 mm) and a height of 500 μm, resulting in a total chamber volume of approximately 8 μL.

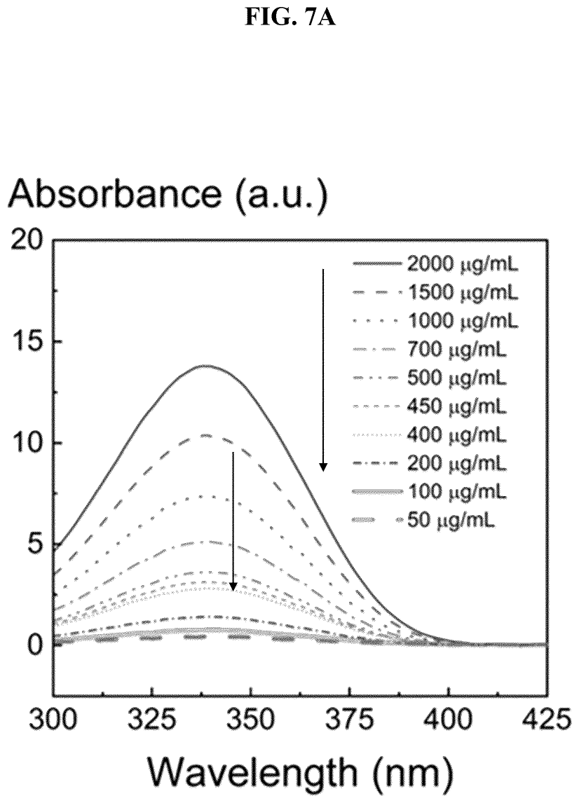

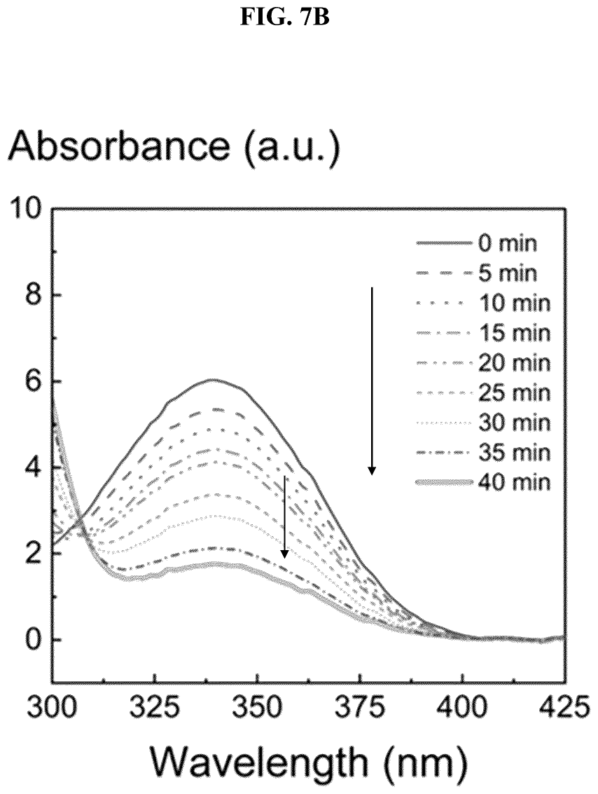

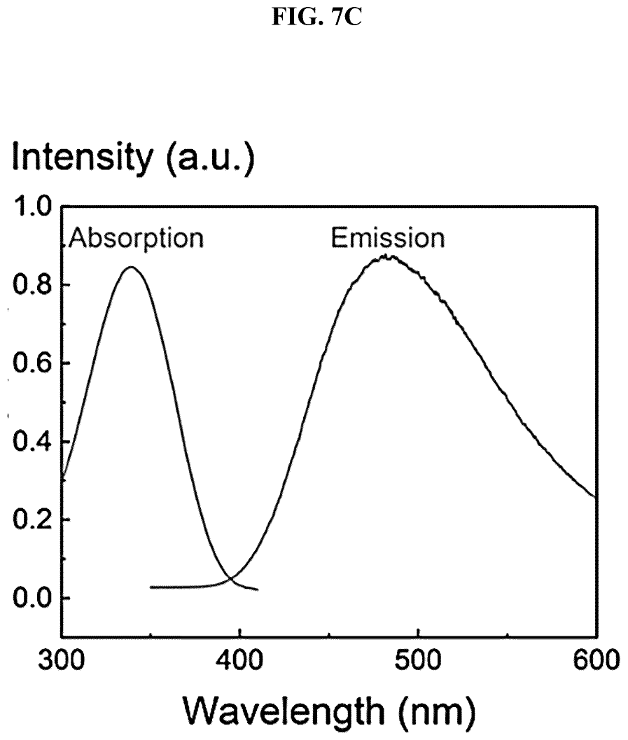

The absorption spectrum of NADH at varying concentrations in phosphate-buffered saline (PBS) solution may be measured with a UV-Visible spectrometer (NanoPhotometer NP80). It indicates that NADH has an absorption peak at 350 nm. FIG. 7A shows a plot of absorbance (in arbitrary units or a.u.) as a function of wavelength (in nanometers or nm) illustrating the concentration-dependent absorption spectra of reduced from of nicotinamide adenine dinucleotide (NADH) in phosphate-buffered saline (PBS) solution according to various embodiments. After adding pyruvate to the solution, NADH is oxidized to NAD⁺ by

$$NADH + Pyruvate \to {NAD}^{+} + Lactate \qquad ( 1 )$$

FIG. 7B shows a plot of absorbance (in arbitrary units or a.u.) as a function of wavelength (in nanometers or nm) illustrating the time-resolved absorption spectra of NADH oxidation in the presence of pyruvate in phosphate-buffered saline (PBS) solution according to various embodiments. FIG. 7B shows that the reaction may lead to the decay of the 350 nm absorption peak. This change in absorption may be pivotal for the sensing mechanism employed by the 2DEG-IPD biosensor array of the photoelectric sensor.

FIG. 7C shows a plot of intensity (in arbitrary units or a.u.) as a function of wavelength (in nanometers or nm) illustrating the absorption and fluorescence (emission) spectra of NADH in phosphate-buffered saline (PBS) solution according to various embodiments. It is worth noticing that NADH exhibits autofluorescence when excited by 355 nm UV light. Any minimal autofluorescence may not overlap with the absorbance measurement at 355 nm, thus having negligible impact on the sensor's accuracy.

The UV light transmitted through the sample in the PDMS holder/chamber may experience attenuation in intensity, which is directly correlated with the NADH concentration present in the sample. The subsequent addition of pyruvate may induce a rapid photocurrent response due to the optical density alteration of the analyte, enabling the rapid detection of NADH levels.

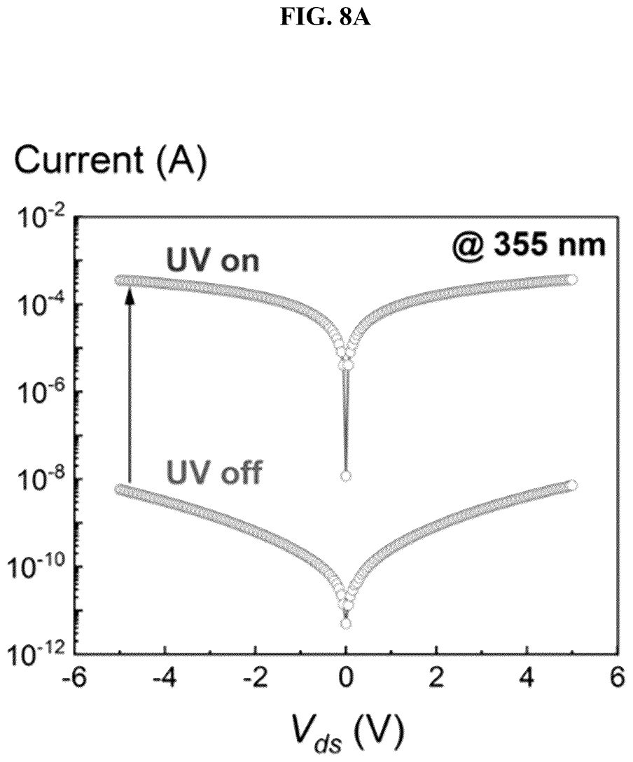

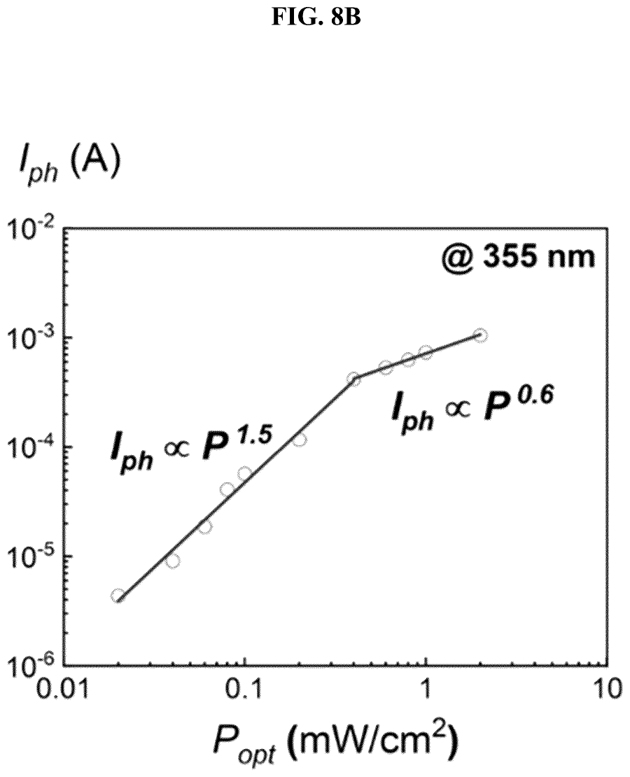

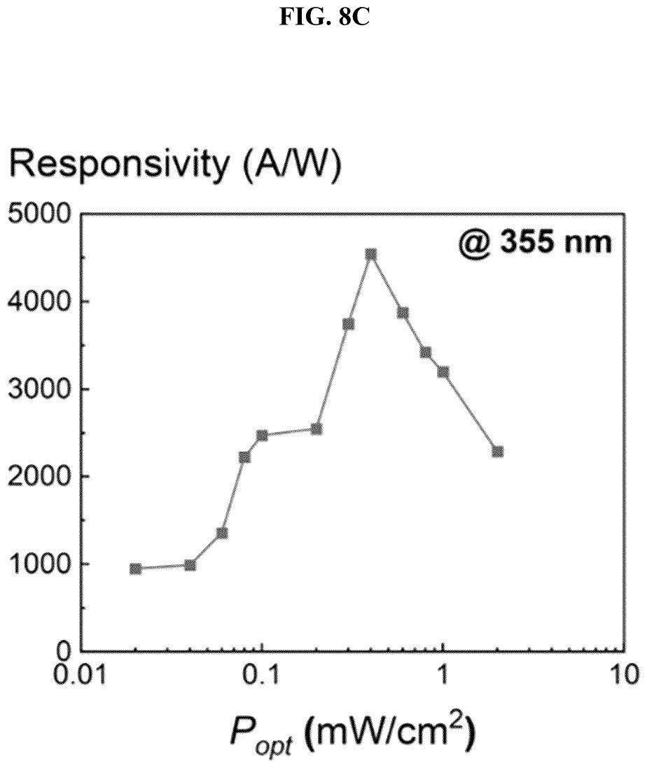

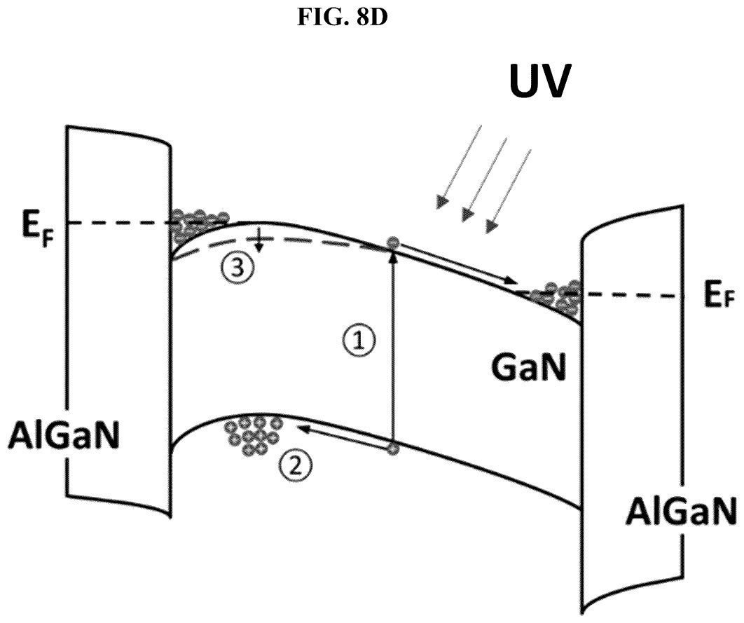

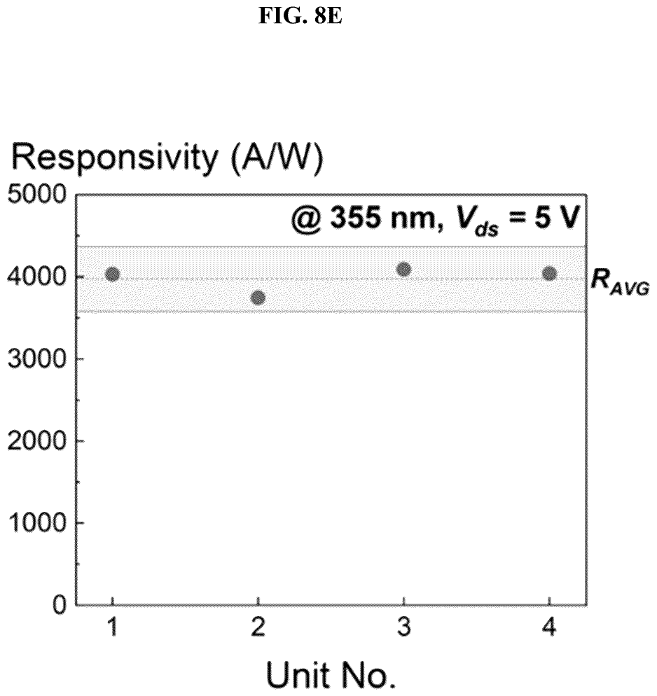

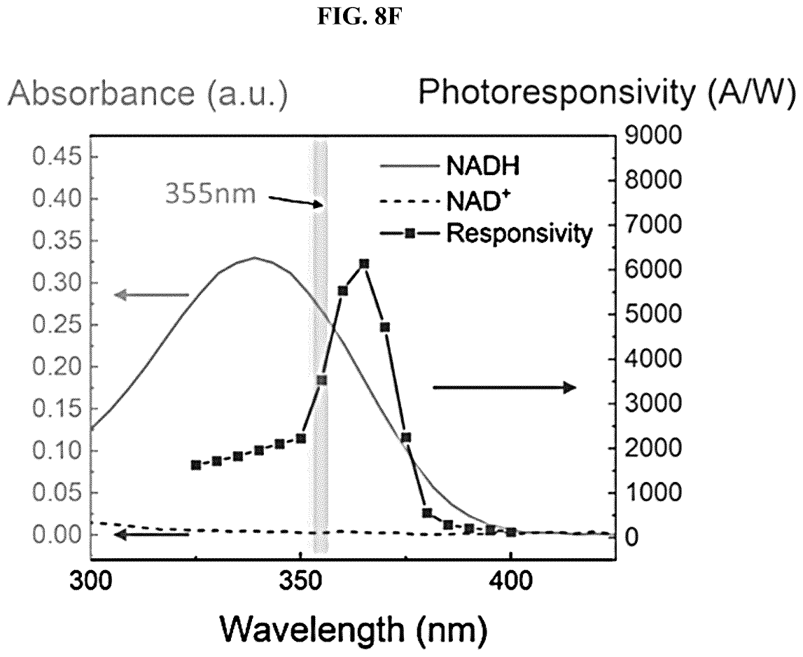

Before the application of 3D multicellular models, a sequence of optoelectronic characteristics was measured. Current-voltage (I-V) characteristics of the devices have been measured by Keithley 2636B source meter under dark and UV light. The UV light has been directed vertically on the devices through an optical fiber (Thorlabs; M30L02). The light source is composed of a broadband 75W Xe lamp (Horiba; LPS 100) light source attached with monochromator (PTI). The incidence of light power on the sample has been calibrated by a silicon PD (Thorlabs; S120VC) integrated to power meter (Thorlabs; PM100A). The drain-source voltage was set at +5 V unless otherwise specified. FIG. 8A shows a plot of current (in Amperes or A) as a function of drain-source voltage V_{ds} (in Volts or V) illustrating the dark current I_{dark} and photocurrent Iₚₕ at a wavelength of 355 nm of the photoelectric sensor according to various embodiments. As shown in FIG. 8A, a low dark current (I_{dark}) of 7.18 nA and a high photocurrent (Iₚₕ) of 0.369 mA at an illumination power intensity of 0.4 mW/cm² were achieved with device unit 1 of the 2DEG-IPD array, leading to a high dark-to-current ratio of 5.1×10⁴. The low I_{dark} may be due to the interdigitated mesa structures of the AlGaN layer that disconnects the 2DEG channel and the passivation effect of SiO₂ insulation layer. Conversely, the high Iₚₕ is contributed by the presence of 2DEG layer. Therefore, it confirms the effectiveness of the AlGaN/GaN 2DEG-IPD for high performance PD operation. Subsequently, the responsivity of the corresponding device was obtained by

$$R = \frac{{I}_{p h} - {I}_{d a r k}}{{P}_{o p t} A} \qquad ( 2 )$$

where Pₒₚₜ is the incident light power intensity, and A is the effective illuminated area of the device. The responsivity was calculated to be 4546 A/W at an illumination power intensity of 0.4 mW/cm². Such high responsivity may enable ultrahigh sensitivity of the sensors, as minor variations in light intensity leads to substantial alterations in Iₚₕ amplitude. Remarkably, the device's performance has surpassed the 100% quantum efficiency, suggesting the existence of an internal gain mechanism within the 2DEG-IPDs. To further evaluate the gain mechanism, the optical power intensity dependent photoresponse for the device unit 1 (i.e., photodetector 1) of the 2×2 2DEG-IPD biosensor array is measured by varying the power intensity from 0.02 to 2 mW/cm². FIG. 8B shows a plot of photocurrent Iₚₕ (in Amperes or A) of the device unit 1 of the biosensor array as a function of optical power intensity Pₒₚₜ(in milli-Watts per square centimeter or mW/cm²) at 355 nm according to various embodiments. FIG. 8C shows a plot of responsivity (in Amperes per Watt or A/W) of the device unit 1 of the biosensor array as a function of optical power intensity Pₒₚₜ (in milli-Watts per square centimeter or mW/cm²) at 355 nm according to various embodiments. The measured Iₚₕ was fitted using the formula below:

$${I}_{photo} = C {P}_{opt}^{θ} \qquad ( 3 )$$

Here, C is a constant, Pₒₚₜ is the optical power intensity, and θ is the empirical coefficient. Under low power illumination (Pₒₚₜ<0.4 mW/cm²), θ>1 was obtained for the measured device, indicating that the internal gain effect dominates. Conversely, at higher power illumination (Pₒₚₜ>0.4 mW/cm²), θ<1 was obtained, which signifies the saturation of the internal gain effect.

FIG. 8D shows an energy band diagram of aluminum gallium nitride/gallium nitride (AlGaN/GaN) heterostructures according to various embodiments. The detailed explanation for the gain mechanism is illustrated in FIG. 8D. Under UV illumination, electron-hole pairs are firstly generated in the intrinsic GaN region (process 1). The photo-generated holes are then drifted and accumulated at the AlGaN/GaN heterojunction (process 2). Thus, the barrier height of the electrons in the 2DEG, Φ_{B}, is lowered by ΔΦ_{B}, which allows the electrons to escape from the 2DEG region (process 3). Ideally, the alteration in carrier concentration in the 2DEG channel Δnₛ is expressed by the following equation:

$$Δ {n}_{s} = \frac{{k}_{b} T {m}^{⋆}}{{πℏ}^{2}} exp ( - \frac{q ( {Φ}_{B} - Δ {Φ}_{B} )}{{k}_{b} T} ) \qquad ( 4 )$$

where k_{b} is the Boltzmann constant, T is the temperature, m* is the effective mass of electron, h is the plank constant. Furthermore, assuming all escaped electrons from 2DEG region enter the conduction band and the photocurrent is due to drift current, photogenerated current can be extracted by the following equation:

$$I = Δ {n}_{s} q {ν}_{n} W \qquad ( 5 )$$

where νₙ is the average electron velocity in the channel, and W is the device width. Upon subjecting the system to low-power illumination, ΔΦ_{B} is caused by an increase in the optical power intensity. This variation leads to an exponential increase in ΔΦ_{B}, which in turn precipitates an exponential rise in the photocurrent, MI. It contributes to the internal gain observed in 2DEG-IPDs. As the power of illumination continues to escalate, there is a concurrent increase in nonidealities such as the recombination within the channel, ultimately culminating in the saturation of the internal gain effect.

The uniformity of the 2×2 2DEG-IPD array was rigorously evaluated. FIG. 8E shows a plot of responsivity (in Amperes per Watt or A/W) as a function of the device unit number (Unit No.) of the 2×2 biosensors array according to various embodiments (Pₒₚₜ=0.3 mW/cm², λ=355 nm, V_{ds}=5 V). Each of the biosensor device units (i.e., photodetectors) demonstrated high responsivity at an illumination power intensity of 0.3 mW/cm² and V_{ds} of +5 V. FIG. 8F shows a plot of absorbance (in arbitrary units or a.u.)/photoresponsivity (in Amperes per Watt or A/W) as a function of wavelength (in nanometers or nm) illustrating the absorption spectrum of NADH/NAD⁺ and the spectral responsivity of the photoelectric sensor according to various embodiments. The 2DEG-IPD array exhibited pronounced responsivity within the 350 to 375 nm wavelength range, aligning with NADH's absorption peak. It causes a marked distinction from NAD⁺, thereby affirming the array's heightened sensitivity for NADH detection.

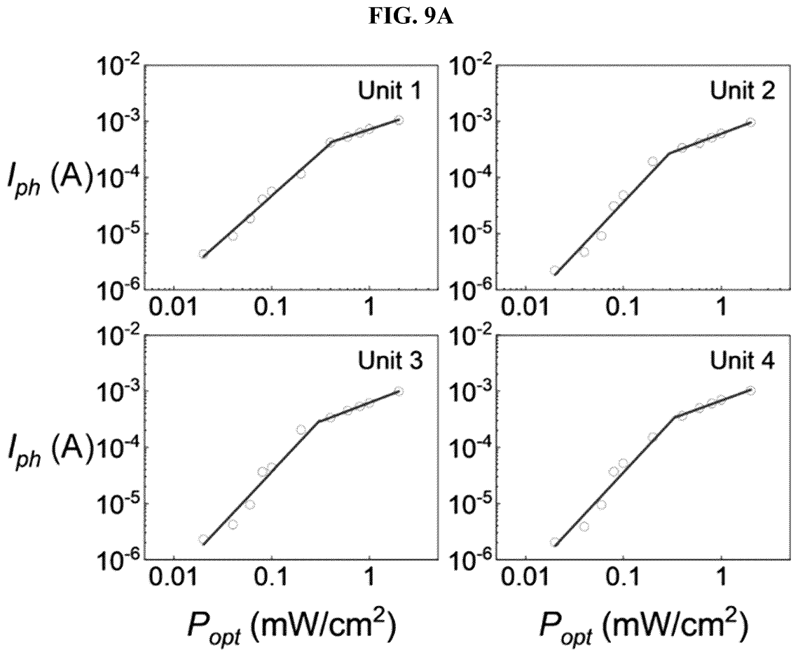

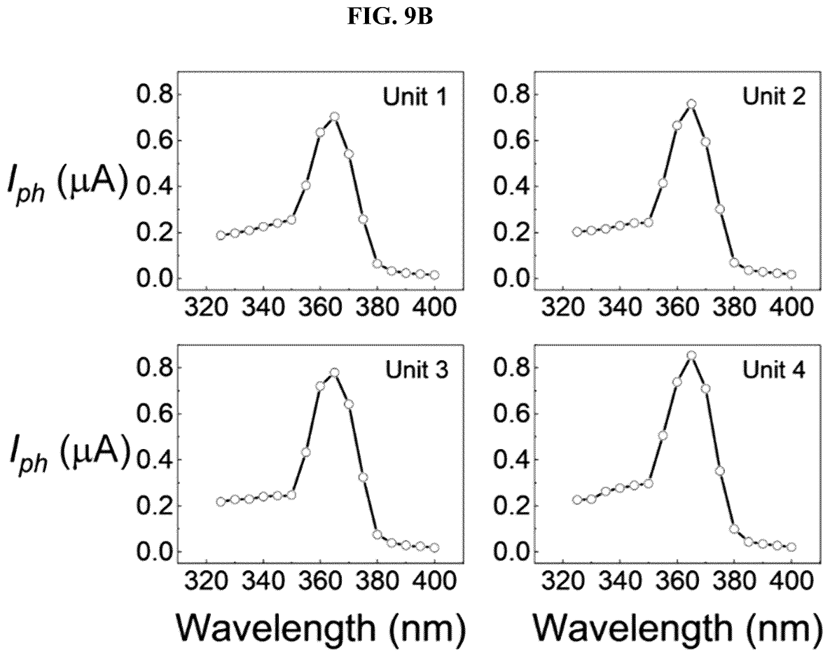

FIG. 9A shows plots of photocurrent Iₚₕ (in Amperes or A) of the device units 1 to 4 of the biosensor array as a function of optical power intensity Pₒₚₜ (in milli-Watts per square centimeter or mW/cm²) according to various embodiments. FIG. 9B shows plots of photocurrent Iₚₕ (in Amperes or A) of the device units 1 to 4 of the biosensor array as a function of wavelength (in nanometers or nm) according to various embodiments.

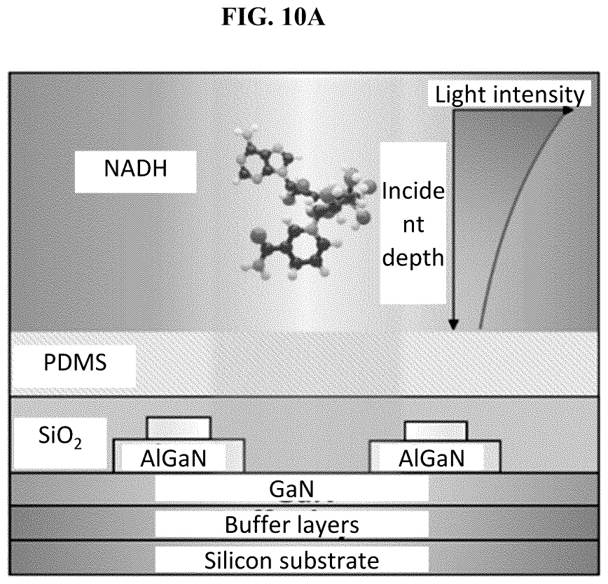

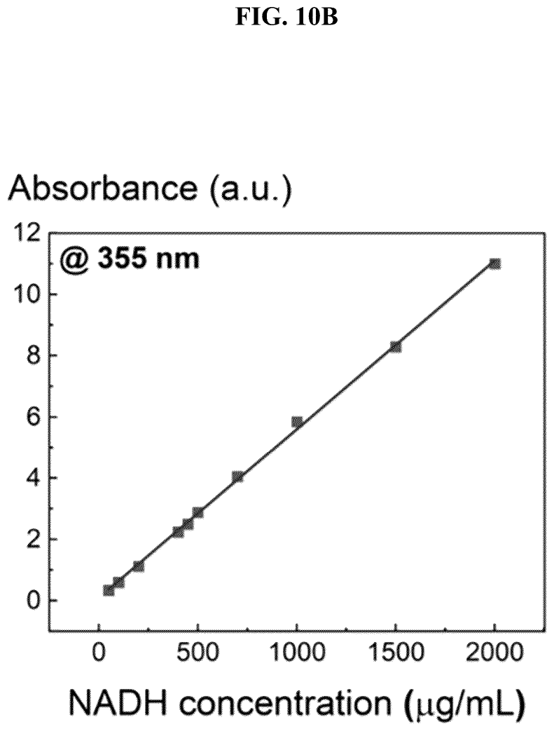

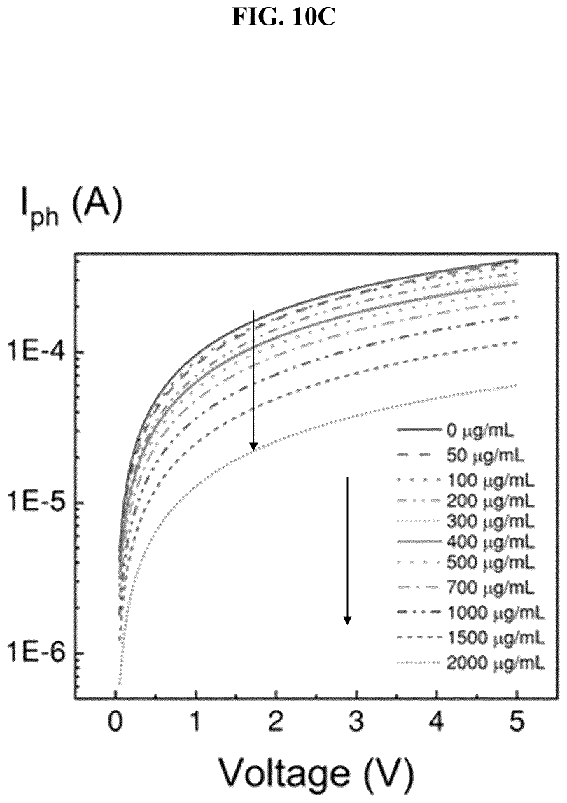

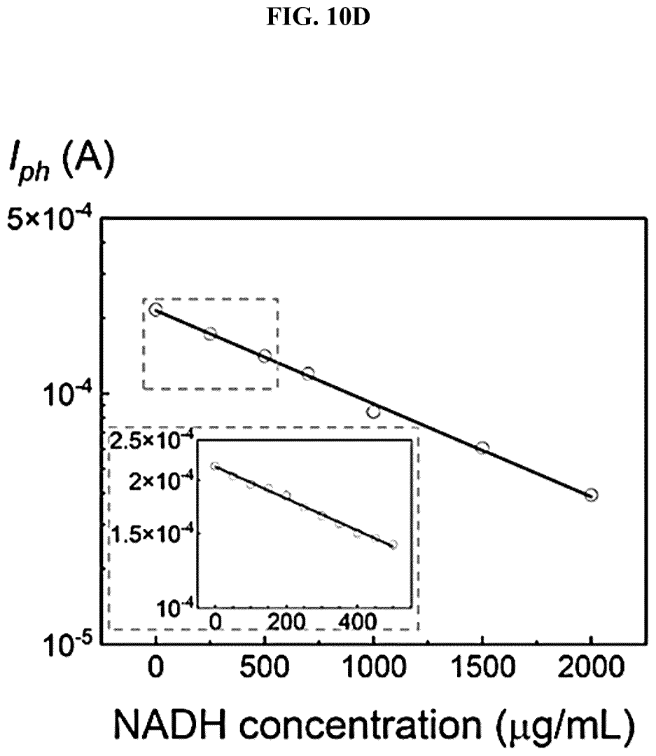

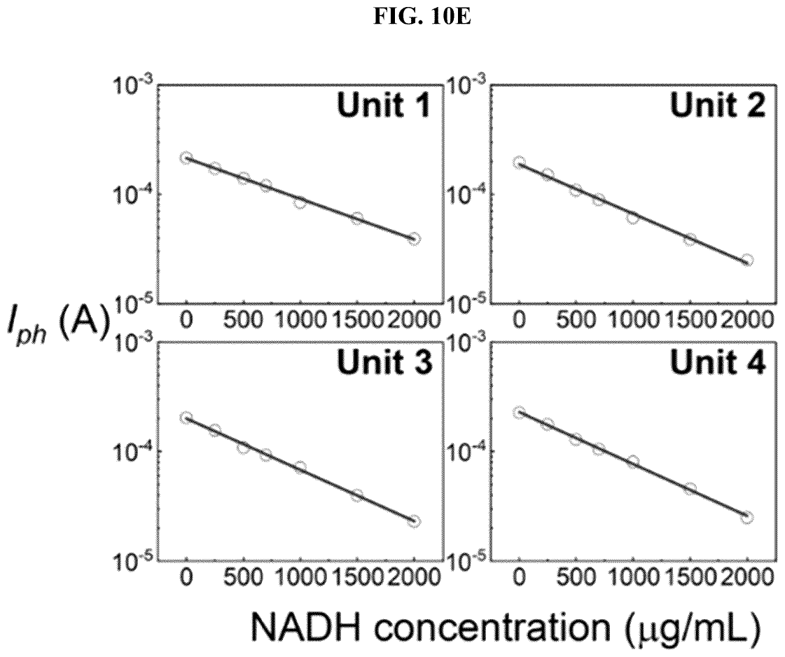

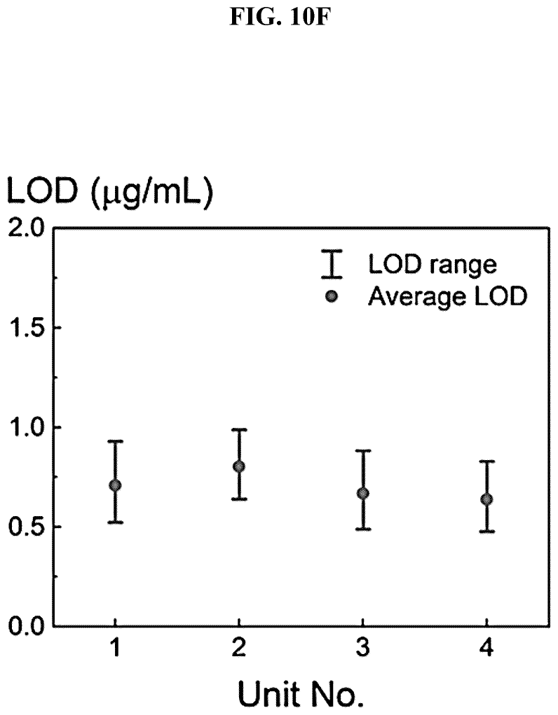

To substantiate the NADH detection capabilities of the 2DEG-IPD biosensor array, an on-chip absorption detection test was conducted using the biosensor array. The detection principle may be based on the quantification of optical transmission disparities, correlating with varying NADH concentrations within the PDMS chamber, situated on the top of the 2DEG-IPD array. FIG. 10A shows a schematic illustrating the detection principle of the photoelectric sensor according to various embodiments. FIG. 10B shows a plot of absorbance (in arbitrary units or a.u.) as a function of NADH concentration (in micrograms per milliliter or μg/mL) illustrating the absorbance of phosphate-buffered saline (PBS) solution with different NADH concentrations according to various embodiments. The optical absorbance of PBS solution spiked with NADH of different concentrations was firstly extracted from FIGS. 7A-B. It confirms that the absorbance values may exhibit a direct proportionality to the NADH concentration.

Next, the PBS solution of a known NADH concentration is loaded into the PDMS chamber placed above the 2DEG-IPD biosensor array. The PDMS chamber was treated with plasma to make it hydrophilic before loaded with PBS/NADH solution. The illumination light is subsequently turned on and photocurrent Iₚₕ is measured. After performing assay with a sample at a particular NADH concentration, the PDMS chamber is replaced with another one at a different NADH concentration for next measurement. The current-voltage (I-V) characteristics for varying NADH concentrations from 0 to 2000 μg/mL of device unit 1 are presented in FIG. 10C. FIG. 10C shows a plot of photocurrent Iₚₕ (in Amperes or A) as a function of drain-source voltage V_{ds} (in Volts or V) illustrating the current-voltage relationship of the device unit 1 according to various embodiments with different NADH concentrations. The measured Iₚₕ was extracted in FIG. 10D. FIG. 10D shows a plot of photocurrent Ip (in Amperes or A) as a function of NADH concentration (in microgram per milliliter or μg/mL) illustrating the linear relationship between Iₚₕ and NADH concentration of device unit 1 according to various embodiments at a drain-source voltage of +5 V. FIG. 10D shows that the photocurrent may decrease with increasing NADH concentration. The inset shows a magnified plot of the boxed region. Iₚₕ for unit 1 exhibited an exponential decline from 2.16×10⁻⁴ A to 3.93×10⁻⁵ A as the NADH concentration increased from 0 to 2000 μg/mL. To evaluate the linear fitting result, the absorbance can be expressed as:

$$A = log \frac{{I}_{i n}}{{I}_{tran}} \qquad ( 6 )$$

where A is the optical absorbance, Iᵢₙ is the incident light power intensity, Iₜᵣₐₙ is the transmitted light power intensity. As A increases proportionally with the concentration of NADH, Iₜᵣₐₙ is expected to decrease exponentially. It is also observed that Iₚₕ is proportional to the

$${P}_{o p t}^{θ} ,$$

suggesting that Iₚₕ may theoretically diminish exponentially with increasing concentration, consistent with the experimental results. In other words, the photocurrent may decrease exponentially with increasing NADH concentration.

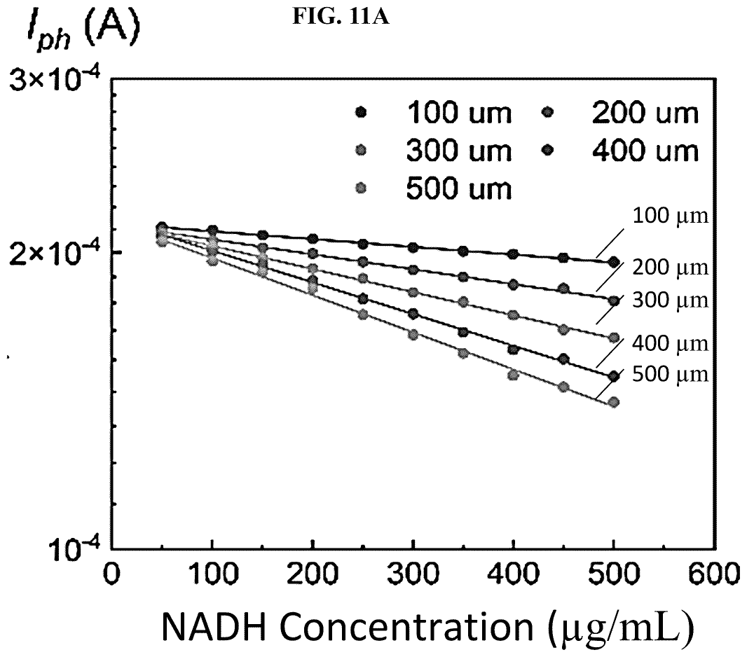

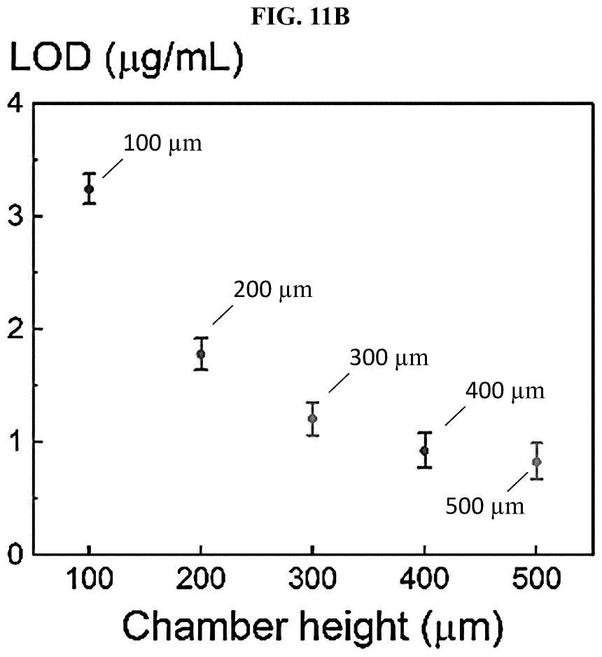

To further assess the uniformity of the 2DEG-IPD biosensor array, the relationship between NADH concentrations and Iₚₕ for the 2×2 2DEG-IPD biosensor array is established. FIG. 10E shows plots of photocurrent Iₚₕ (in Amperes or A) of the device units 1 to 4 of the biosensor array as a function of NADH concentration (in microgram per milliliter or μg/mL) illustrating linear relationship between Iₚₕ and NADH concentration of all four device units according to various embodiments at a drain-source voltage of +5 V. Each of the units demonstrated highly consistent sensing characteristics across the NADH concentration range from 0 to 2000 μg/mL. FIG. 10F shows a plot of limit of detection LOD (in microgram per milliliter or μg/mL) as a function of device unit number (Unit No.) illustrating LOD of all four device units of the biosensor array according to various embodiments. FIG. 10F shows the limit of detection (LOD) values for the 2DEG-IPD biosensor array using the equation LOD=3σ/kₛₗₒₚₑ, where σ is the standard deviation of the background signal measured from a blank control, and kₛₗₒₚₑ is the slope of the fitting curve. The variations of sensing characteristics among the units are likely attributed to the variations of the photoresponse. According to Equation (6), the optical path length of the chamber influences the sensitivity and detection limit of the sensor. To confirm the impact of chamber size on the sensor's performance, the dependence of chamber height on Iₚₕ and LOD of device unit 1 is shown in FIGS. 11A-B.

FIG. 11A shows a plot of photocurrent Iₚₕ (in Amperes or A) as a function of NADH concentration (in microgram per milliliter or μg/mL) illustrating NADH concentration-dependent Iₚₕ for varying chamber height of the photoelectric sensor according to various embodiments from 100 μm to 500 μm. FIG. 11B shows a plot of limit of detection LOD (in microgram per milliliter or μg/mL) as a function of chamber height (in micrometer or μm) illustrating the effect of chamber height on LOD of the various device units according to various embodiments. The LOD shows an exponential decay with the chamber height increasing from 100 μm to 500 μm. Overall, the 2DEG-IPD biosensor array shows a low average LOD value of around 0.7 μg/mL, and a high sensitivity of 0.19 μA μg⁻¹ mL. The analytical performance of the on-chip NADH sensor may be comparable with other electrochemical sensors. Most importantly, the device can be used for large-scale NADH sensing in tissues and tumors on a single chip.

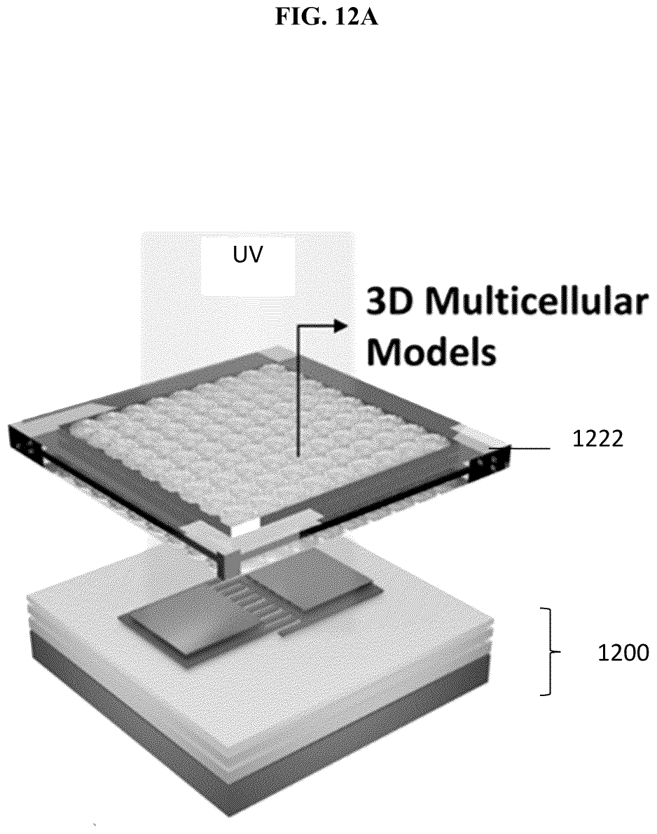

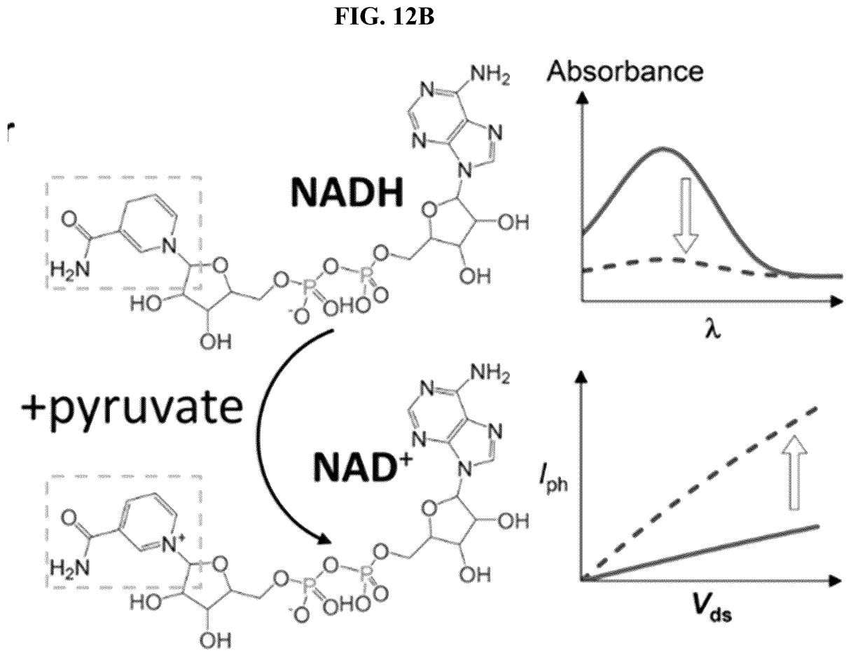

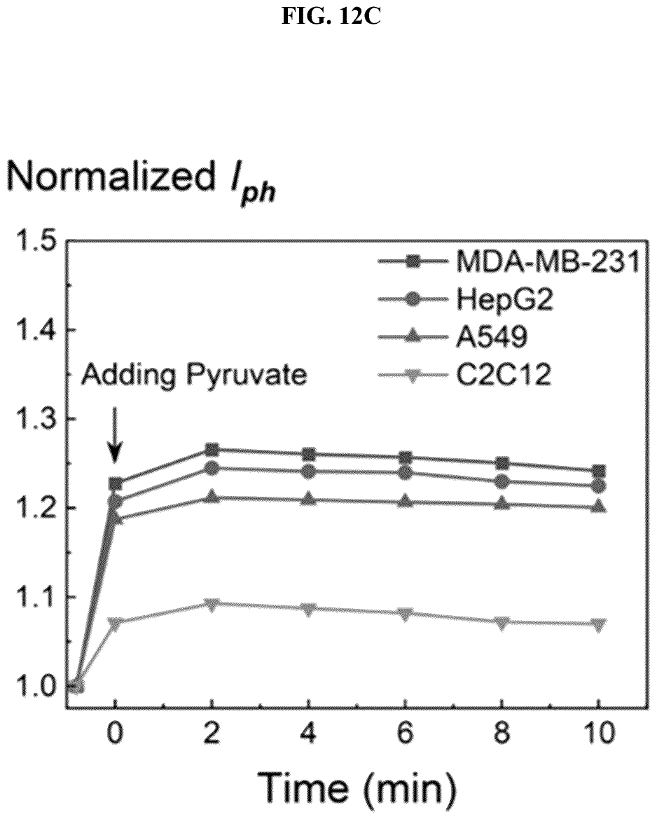

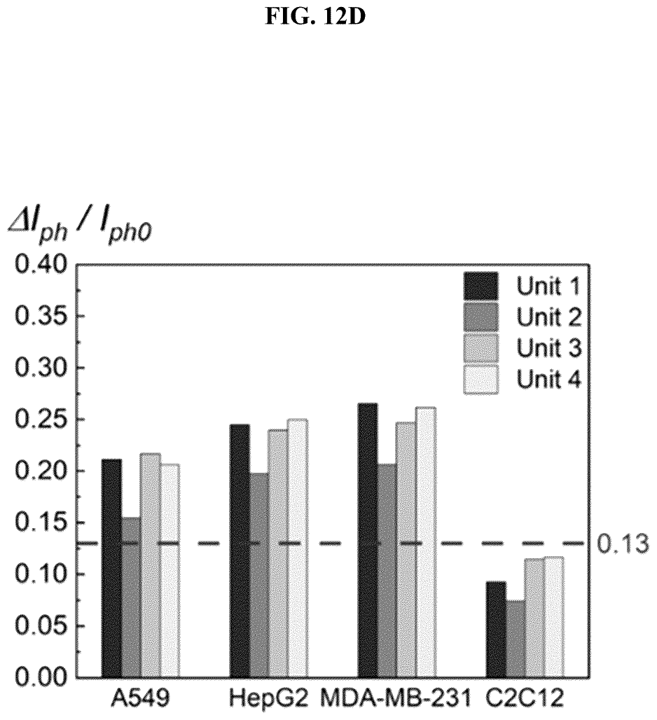

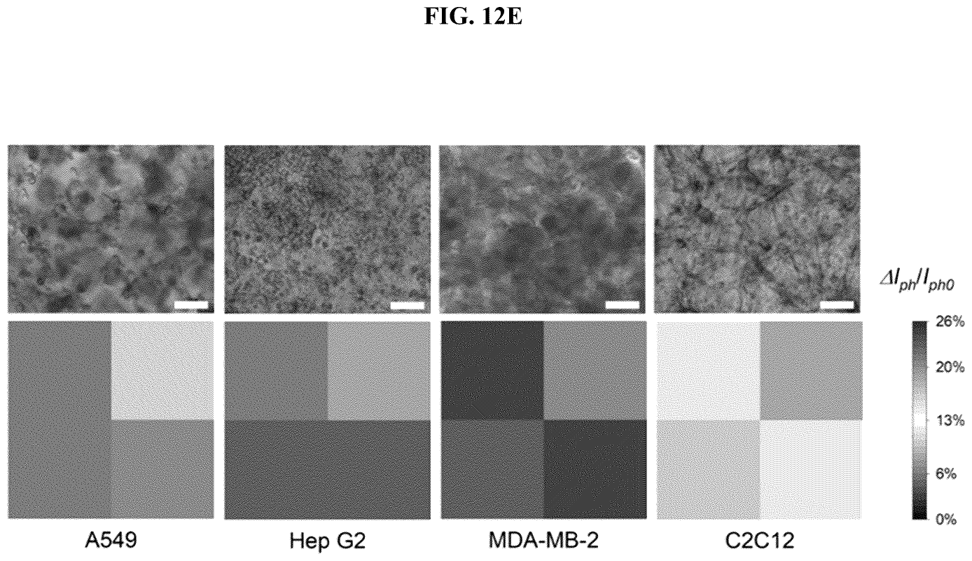

Subsequently, as a proof of concept, rapid on-chip detection of NADH in 3D multicellular models is demonstrated. FIG. 12A shows a schematic of NADH sensing with three-dimensional (3D) multicellular models according to various embodiments. To form the 3D multicellular models, C2C12 cells along with three cancer cell lines (MDA-MB-231, HepG2, and A549 purchased from ATCC) are utilized. The cells, at a concentration of 2×10⁶/mL, were mixed with Matrigel (3 mg/mL, Corning) individually. The cell-Matrigel solutions were then poured into PDMS chambers 1222 and left in a 37° C. incubator for 30 minutes. Upon curing of the Matrigel, the cells were cultured in Dulbecco's Modified Eagle Medium (DMEM) supplemented with 10% fetal bovine serum (FBS) and 100 U/mL penicillin/streptomycin. Following a 2-day culture period, the 3D multicellular models were formed with a thickness of ˜300 μm. Then, the models were affixed on top of the photoelectric sensor 1200 with the biosensor array for testing.

FIG. 12B shows an illustration of on-chip NADH sensing mechanism according to various embodiments. As illustrated in FIG. 12B, to eliminate the noise signal of light scattering and absorption by other biomolecules, the experiment is designed to treat the sample with exogenous pyruvate, resulting in cellular NADH oxidized to NAD⁺. With the 2DEG-IPD biosensor array, the aforementioned reaction is discernible by a reduction in absorbance at 355 nm and a concomitant rise in Iₚₕ. The selectivity of this detection method is enhanced by the specificity of the absorption characteristics of the oxidation process of NADH compared to other cellular components and exogenous pyruvate. Thus, the detection system is highly selective for NADH, making it ideal for studying metabolic activity in multicellular models, especially in distinguishing between normal and cancerous cells.

FIG. 12C shows a plot of normalized photocurrent Iₚₕ as a function of time (in minutes or min) illustrating normalized photocurrent dynamics after adding 500 μM exogenous pyruvate into each type of three-dimensional (3D) multicellular models in device unit 1 according to various embodiments. A swift Iₚₕ response was observed across all samples, with a peak reached at two minutes post-treatment, followed by a gradual recovery. It was consistent with previous reports of the kinetics of NADH treated with pyruvate. Upon pyruvate interaction, the cancer cell lines demonstrated the maximum normalized Iₚₕ of 1.27, 1.24, and 1.21, respectively. It indicates a pronounced metabolic activity compared to the normal cell line, which exhibited a lower increase to 1.07.

The uniformity of change in photocurrent/initial photocurrent (ΔIₚₕ/Iₚₕ₀) from each device unit for each cell type is also quantified. According to the different NADH concentration variation of the multicellular models, cellular NADH levels were summarized in FIG. 12D. FIG. 12D shows a plot of change in photocurrent/initial photocurrent (ΔIₚₕ/Iₚₕ₀) as a function of device unit illustrating ΔIₚₕ/Iₚₕ₀ results of each device unit with 4 types of three-dimensional (3D) multicellular models according to various embodiments. It represents the ΔIₚₕ/Iₚₕ₀ response of each 2DEG-IPD unit in the 2×2 array to different multicellular models (MDA-MB-231, HepG2, A549, and C2C12). The cancerous samples consistently presented elevated NADH levels, corroborating with literature on the metabolic characteristics of cancer cells. Variations in ΔIₚₕ/Iₚₕ₀ among the four device units for each 3D multicellular model were mainly due to the different photoresponse among device units, consistent with the different slopes of photoresponse curve in FIG. 9A.). Subsequently, a cutoff value of 13% for ΔIₚₕ/Iₚₕ₀ was selected for cancer detection. Employing this threshold, on-chip assays for another group of 3D multicellular models cultured under the same conditions were carried out. FIG. 12E shows microscopy images of four three-dimensional (3D) multicellular models with spatial photocurrent/initial photocurrent (ΔIₚₕ/Iₚₕ₀) results from four device units according to various embodiments. The scale bar represents 100 μm. As shown in FIG. 12E, with this ΔIₚₕ/Iₚₕ₀ threshold, it may be observed that the on-chip sensor showed precise detection capabilities for the 3D multicellular models.

Various embodiments may relate to a miniaturized rapid on-chip photoelectric sensor based on 2×2 AlGaN/GaN 2DEG-IPDs for the detection of NADH concentration in cells. By addressing the growing demand for rapid NADH quantification, various embodiments may offer significant advancements over conventional methods, providing high sensitivity in a miniaturized device. The sensing mechanism of the 2DEG-IPD array was thoroughly elucidated, showcasing its potential for NADH detection. Optoelectronic performance evaluations revealed the exceptional characteristics of the device, including low I_{dark}, high Iₚₕ, and ultrahigh responsivity, which may be crucial for achieving sensitive detection of NADH. Through extensive experimentation, the NADH sensing ability of the 2×2 2DEG-IPD biosensor array is validated. By measuring the difference in optical transmission caused by varying concentrations of NADH, various embodiments may exhibit a linear response to NADH concentration changes. Various embodiments may also achieve the consistency and reliability across different units, with an average LOD value of 0.7 μg/mL (1.05 μM), showcasing its potential for practical applications. The versatility of the photoelectric sensor was further demonstrated through the rapid on-chip detection of NADH in 3D multicellular models. Various embodiments may be capable of rapidly distinguishing between normal and cancerous cell samples based on cellular NADH levels. Therefore, the highly sensitive and miniaturized on-chip device according to various embodiments may represent a significant advancement in the field of NADH sensing. With its potential for high-throughput testing and point-of-care applications, various embodiments may hold a great promise for improving healthcare diagnostics and disease management.

1. A photodetector comprising:
a semiconductor substrate;
an aluminium nitride (AlN) layer on the semiconductor substrate;
one or more aluminium gallium nitride (AlGaN) layers over the aluminium nitride (AlN) layer;
a doped gallium nitride (GaN) layer over the one or more aluminium gallium nitride (AlGaN) layers;
a first mesa structure on a first portion of the doped gallium nitride (GaN) layer; and
a second mesa structure spaced from the first mesa structure and on a second portion of the doped gallium nitride (GaN) layer;
wherein the first mesa structure comprises:
a first undoped gallium nitride (GaN) layer on the doped gallium nitride (GaN) layer; and
a first aluminium gallium nitride (AlGaN) layer on the first undoped gallium nitride (GaN) layer;
wherein the second mesa structure comprises:
a second undoped gallium nitride (GaN) layer on the doped gallium nitride (GaN) layer; and
a second aluminium gallium nitride (AlGaN) layer on the second undoped gallium nitride (GaN) layer; and
wherein the photodetector further comprises:
a first electrode over the first mesa structure; and
a second electrode over the second mesa structure.

2. The photodetector according to claim 1,
wherein the first mesa structure and the second mesa structure form an interdigitated arrangement.

3. The photodetector according to claim 1,
wherein the doped gallium nitride (GaN) layer comprises carbon or iron.

4. The photodetector according to claim 1,
wherein the semiconductor substrate is a silicon substrate, a silicon carbide substrate or a sapphire substrate.

5. The photodetector according to claim 4,
wherein the semiconductor substrate is the silicon substrate; and
wherein the silicon substrate is a silicon (111) substrate.

6. The photodetector according to claim 1,
wherein the photodetector is a two-dimensional electron gas interdigitated photodetector (2DEG-IPD).

7. A photoelectric sensor comprising:
one or more photodetectors, each of the one or more photodetectors comprising:
a semiconductor substrate;
an aluminium nitride (AlN) layer on the semiconductor substrate;
one or more aluminium gallium nitride (AlGaN) layers over the aluminium nitride (AlN) layer;
a doped gallium nitride (GaN) layer over the one or more aluminium gallium nitride (AlGaN) layers;
a first mesa structure on a first portion of the doped gallium nitride (GaN) layer; and
a second mesa structure spaced from the first mesa structure and on a second portion of the doped gallium nitride (GaN) layer;
wherein the first mesa structure comprises:
a first undoped gallium nitride (GaN) layer on the doped gallium nitride (GaN) layer; and
a first aluminium gallium nitride (AlGaN) layer on the first undoped gallium nitride (GaN) layer;
wherein the second mesa structure comprises:
a second undoped gallium nitride (GaN) layer on the doped gallium nitride (GaN) layer; and
a second aluminium gallium nitride (AlGaN) layer on the second undoped gallium nitride (GaN) layer; and
wherein the photodetector further comprises:
a first electrode over the first mesa structure; and
a second electrode over the second mesa structure;
an electrically insulating layer over the one or more photodetectors; and
a holder on the electrical insulating layer, the holder configured to hold a sample.

8. The photoelectric sensor according to claim 7,
wherein the electrically insulating layer comprises silicon oxide, aluminium oxide, silicon nitride, hafnium oxide, or any combination thereof.

9. The photoelectric sensor according to claim 7,
wherein the holder comprises polydimethylsiloxane (PDMS), poly(methyl methacrylate) (PMMA), cyclic olefin copolymer (COC), cyclic olefin polymers (COP), quartz, or any combination thereof.

10. The photoelectric sensor according to claim 7,
wherein the photoelectric sensor is configured to be used in absorbance-based chemical or biochemical sensing.

11. A method of forming a photodetector, the method comprising:
forming an aluminium nitride (AlN) layer on a semiconductor substrate;
forming one or more aluminium gallium nitride (AlGaN) layers over the aluminium nitride (AlN) layer;
forming a doped gallium nitride (GaN) layer over the one or more aluminium gallium nitride (AlGaN) layers;
forming a first mesa structure on a first portion of the doped gallium nitride (GaN) layer; and
forming a second mesa structure spaced from the first mesa structure and on a second portion of the doped gallium nitride (GaN) layer;
wherein the first mesa structure comprises:
a first undoped gallium nitride (GaN) layer on the doped gallium nitride (GaN) layer; and
a first aluminium gallium nitride (AlGaN) layer on the first undoped gallium nitride (GaN) layer; and
wherein the second mesa structure comprises:
a second undoped gallium nitride (GaN) layer on the doped gallium nitride (GaN) layer; and
a second aluminium gallium nitride (AlGaN) layer on the second undoped gallium nitride (GaN) layer; and
wherein the method further comprises:
forming a first electrode over the first mesa structure; and
forming a second electrode over the second mesa structure.

12. The method according to claim 11,
wherein forming the first mesa structure and the second mesa structure comprises:
depositing undoped gallium nitride (GaN) on the doped gallium nitride (GaN) layer;
depositing aluminium gallium nitride (AlGaN) on the deposited undoped gallium nitride (GaN);
depositing photoresist on the deposited aluminium gallium nitride (AlGaN);
patterning the deposited photoresist; and
etching the deposited undoped gallium nitride (GaN) and the deposited aluminium gallium nitride (AlGaN) using the patterned photoresist to form the first mesa structure comprising the first undoped gallium nitride (GaN) layer and the first aluminium gallium nitride (AlGaN) layer, and the second mesa structure comprising the second undoped gallium nitride (GaN) layer and the second aluminium gallium nitride (AlGaN) layer.

13. A method of forming a photoelectric sensor, the method comprising:
forming an electrical insulating layer over one or more photodetectors, each of the one or more photodetectors comprising:
a semiconductor substrate;
an aluminium nitride (AlN) layer on the semiconductor substrate;
one or more aluminium gallium nitride (AlGaN) layers over the aluminium nitride (AlN) layer;
a doped gallium nitride (GaN) layer over the one or more aluminium gallium nitride (AlGaN) layers;
a first mesa structure on a first portion of the doped gallium nitride (GaN) layer; and
a second mesa structure spaced from the first mesa structure and on a second portion of the doped gallium nitride (GaN) layer;
wherein the first mesa structure comprises:
a first undoped gallium nitride (GaN) layer on the doped gallium nitride (GaN) layer; and
a first aluminium gallium nitride (AlGaN) layer on the first undoped gallium nitride (GaN) layer;
wherein the second mesa structure comprises:
a second undoped gallium nitride (GaN) layer on the doped gallium nitride (GaN) layer; and
a second aluminium gallium nitride (AlGaN) layer on the second undoped gallium nitride (GaN) layer; and
wherein the photodetector further comprises:
a first electrode over the first mesa structure; and
a second electrode over the second mesa structure; and
forming a holder on the dielectric layer, the holder configured to hold a sample.

14. A method of determining a concentration of a substance in a sample, the method comprising:
providing the sample into a photoelectric sensor, the photoelectric sensor comprising:
one or more photodetectors, each of the one or more photodetectors comprising:
a semiconductor substrate;
an aluminium nitride (AlN) layer on the semiconductor substrate;
one or more aluminium gallium nitride (AlGaN) layers over the aluminium nitride (AlN) layer;
a doped gallium nitride (GaN) layer over the one or more aluminium gallium nitride (AlGaN) layers;
a first mesa structure on a first portion of the doped gallium nitride (GaN) layer; and
a second mesa structure spaced from the first mesa structure and on a second portion of the doped gallium nitride (GaN) layer;
wherein the first mesa structure comprises:
a first undoped gallium nitride (GaN) layer on the doped gallium nitride (GaN) layer; and
a first aluminium gallium nitride (AlGaN) layer on the first undoped gallium nitride (GaN) layer;
wherein the second mesa structure comprises:
a second undoped gallium nitride (GaN) layer on the doped gallium nitride (GaN) layer; and
a second aluminium gallium nitride (AlGaN) layer on the second undoped gallium nitride (GaN) layer; and
wherein the photodetector further comprises:
a first electrode over the first mesa structure; and
a second electrode over the second mesa structure;
an electrically insulating layer over the one or more photodetectors; and
a holder on the electrical insulating layer, the holder configured to hold a sample;
illuminating the sample with an ultraviolet light;
determining a photocurrent from the one or more photodetectors in response to the ultraviolet light passing through the sample; and
determining a concentration of the substance based on the photocurrent.

15. The method according to claim 14,
wherein determining the concentration of the substance based on the photocurrent comprises:
determining, based on the photocurrent, a change in intensity of the ultraviolet light after passing through the sample;
wherein the concentration of the substance is determined based on the change in intensity of the ultraviolet light.

16. The method according to claim 14,
wherein the substance is a reduced from of nicotinamide adenine dinucleotide, glucose, lactate or nitrate.
